(19) United States
(12) Patent Application Publication
(10) Pub. No.: US 2024/0061141 A1
(43) Pub. Date: Feb. 22, 2024

(54) Spectral Differential Equation Approximation Method for Mixed Potential Green's Function in Multilayered Media

(71) Applicant: UNIVERSITY OF MANITOBA, Winnipeg (CA)

(72) Inventors: Vladimir I. Okhmatovski, Winnipeg (CA); Xinbo Li, Winnipeg (CA); Ian Jeffrey, Burnaby (CA)

(21) Appl. No.: 18/256,756

(22) PCT Filed: Dec. 9, 2021
(86) PCT No.: PCT/IB2021/061537

§ 371 Date: Jun. 9, 2023

Related U.S. Application Data
(60) Provisional application No. 63/224,234, filed on Jul. 21, 2021.
(60) Provisional application No. 63/123,285, filed on Dec. 9, 2020.

(51) Int. Cl. G01V 3/38; G06F 17/13

(52) U.S. Cl. CPC G01V 3/38; G06F 17/13

(57) ABSTRACT

The invention provides a method to compute the mixed potential contributions to electric and magnetic field in multilayered media, which can be applied in microwave engineering, integrated circuit analysis, and remote sensing. The Spectral Differential Equation Approximation Method (SDEAM) for solving Michalski-Zheng's mixed-potential Green's functions in fully shielded, partially open, and fully open multilayered media are described. The main advantage of SDEAM over other methods is that for a fixed location of the source elevation z′, it does not require fitting from scratch for every z, z′, and ρ combination. Because of this advantage, SDEAM can be superior in both performance and accuracy to other existing methods. The well-established boundary value problem numerical solvers also provide SDEAM with robustness for miscellaneous planar multilayered structures.

### FIELD OF INVENTION

The present invention relates to electromagnetic analysis in uniaxially anisotropic multilayered media, and more particularly, computing the fields according to Michalski-Zheng's mixed potential formulations, while the mixed potential Green's functions are computed using the Spectral Differential Equation Approximation Method (SDEAM).

### BACKGROUND OF THE INVENTION

Electromagnetic analysis of complex composite structures embedded in planar layered media plays a critical role in microwave engineering with applications ranging from the design of microwave components, high-speed interconnects, and metasurfaces to remote sensing of sub-terrain natural resources and high-power installations.

For the electromagnetic analysis on such structures, the approach based on an method of moment (MoM) discretization of the integral equations in mixed potential form, proposed by Michalski and Zheng in paper titled “Electromagnetic Scattering and Radiation by Surfaces of Arbitrary Shape in Layered Media, Part I: Theory” and “Electromagnetic Scattering and Radiation by Surfaces of Arbitrary Shape in Layered Media, Part II: Implementation and Results for Contiguous Half-spaces” published by IEEE Transactions on Antennas and Propagation in 1990, has been particularly popular, because these mixed potential integral equations do not feature hypersingular kernels by shifting of the differential operators to the basis and testing functions in MoM, hence, enabling the use of existing methods for handling singular integrals. It addition to offering the geometric flexibility, it also supports the use of techniques for low-frequency stabilization. Additionally, MoM discretization of integral equations in mixed-potential form can be exactly cast to the point-based Locally Corrected Nyström discretization for efficient acceleration with fast algorithms.

The key aspect of the MoM solution to the integral equations in mixed potential form is construction of their pertinent mixed-potential Green's functions. These mixed potential Green's functions are formulated by Michalski and Mosig in paper titled “Multilayered Media Green's Functions in Integral Equation Formulations” published by IEEE Transactions on Antennas and propagation in 1997. The formulation of mixed potential Green's functions constitutes a two-stage process. In the first stage, vector and scalar potential Green's function spectra are stated as solutions of appropriately constructed transmission line Telegrapher's equations governing voltages and currents related to the field components. Since these Telegrapher's equations feature point sources as the excitation functions, their solutions are corn nonly referred to as the Transmission Line Green's Functions (TLGFs). In the second stage, inverse Fourier transforms of the mixed-potential Green's function spectra (a.k.a. Sommerfeld integrals (SIs)) must be performed.

Despite their one-dimensional (1D) nature, evaluation of the SIs is a computationally heavy task due to the oscillatory, singular and slowly-convergent behaviour of their integrands. The known numerical methods for evaluating SIs include discrete complex image method which lacks robustness and robust but expensive extrapolation methods.

### BRIEF SUMMARY OF THE INVENTION

According to one aspect of the invention, there is provided a method of electromagnetic analysis of one or more elements in uniaxially anisotropic multilayered media, the method comprising:
(i) representing one or both of the electric field and the magnetic field in multilayered media due to given electric current J and magnetic current M in the form containing mixed potential contributions [symbol] K̅^{A}, J [symbol] , ∇ [symbol] G^{Φ}, ∇′·J [symbol] , [symbol] K̅^{F}, M [symbol] , and ∇ [symbol] G^{Ψ}, ∇′·M [symbol] , the electric field being expressed as

$$E = j {ωμ}_{0} 〈 {\overline{K}}^{A} , J 〉 + \frac{1}{j {ωε}_{0}} ∇ 〈 {G}^{Φ} , {∇}^{′} \cdot J 〉 + 〈 {\overline{G}}^{EM} , M 〉 , \qquad ( 1 )$$

and the magnetic field being expressed as

$$H = j {ωε}_{0} 〈 {\overline{K}}^{F} , M 〉 + \frac{1}{j {ωμ}_{0}} ∇ 〈 {G}^{Ψ} , {∇}^{′} \cdot M 〉 + 〈 {\overline{G}}^{HJ} , J 〉 , \qquad ( 2 )$$

where the dyadic K̅^{A} has components

$${\overline{K}}^{A} = [ \begin{matrix}{K}_{xx}^{A} & 0 & {K}_{yz}^{A} \\ 0 & {K}_{yy}^{A} & {K}_{yz}^{A} \\ {K}_{zx}^{A} & {K}_{zy}^{A} & {K}_{zz}^{A}\end{matrix} ] , \qquad ( 3 )$$

and its spectral domain components are defined by equivalent transmission line Green's functions (TLGFs) Vᵢ^{p}, Vᵥ^{p}, Iᵢ^{p}, and Iᵥ^{p}, where for the transverse magnetic (TM) polarization p=e and for the transverse electric (TE) polarization p=h, as

$${\tilde{K}}_{xx}^{A} = {\tilde{K}}_{yy}^{A} = \frac{1}{j {ωμ}_{0}} {V}_{i}^{h} , \qquad ( 4 )$$

$${\tilde{K}}_{xz}^{A} = \frac{{μ}_{t}^{′} {k}_{x}}{{jk}_{ρ}^{2}} ( {V}_{v}^{h} - {V}_{v}^{e} ) , \qquad ( 5 )$$

$${\tilde{K}}_{yz}^{A} = \frac{{μ}_{t}^{′} {k}_{y}}{{jk}_{ρ}^{2}} ( {V}_{v}^{h} - {V}_{v}^{e} ) , \qquad ( 6 )$$

$${\tilde{K}}_{zz}^{A} = \frac{1}{j {ωε}_{0}} [ ( \frac{{μ}_{t}}{{ε}_{z}^{′}} + \frac{{v}^{e} {μ}_{t}^{′}}{{ε}_{t}^{′}} - \frac{{μ}_{t}^{′} {k}_{t}^{2}}{{ε}_{t} {k}_{ρ}^{2}} ) {I}_{v}^{e} + \frac{{k}_{0}^{2} {μ}_{t} {μ}_{t}^{′}}{{k}_{ρ}^{2}} ] , \qquad ( 7 )$$

$${\tilde{G}}^{Φ} = \frac{j {ωε}_{0}}{{k}_{ρ}^{2}} ( {V}_{i}^{h} - {V}_{i}^{e} ) , \qquad ( 8 )$$

and the spatial domain K̅^{A} and G^{Φ} are obtained by performing inverse Fourier transform of (4) to (8), in which, kₜ²=k₀²μₜεₜ, k₀²=ω²μ₀ε₀, the relative permittivity dyadic ε̅=Īₜεₜ+\hat{z}\hat{z}ε_{z}, relative permeability dyadic μ̅=Īₜμₜ+\hat{z}\hat{z}μ_{z}, and electric and magnetic anisotropy ratio v^{e}=εₜ/ε_{z} and v^{h}=μₜ/μ_{z}, where the subscripts t and z mean the parameter in the transverse plane and z direction, respectively, and ε′ and μ′ represent physical quantities associated with the layer containing the source elevation z′; and
(ii) evaluating mixed potential Green's functions K̅^{A} and G^{Φ} using the Spectral Differential Equation Approximation Method (SDEAM) to solve for the electric field according to (1), while mixed potential Green's functions K̅^{F} and G^{Ψ} in mixed representation of H (2) is related to TLGFs according to (4) to (8) and replacement of symbols A→F, Φ→Ψ, ε→μ, μ→ε, V→I, I→V, v→i, i→v, e→h, h→e and also can be solved by SDEAM.

The method includes SDEAM which approximates the Green's function spectra with rational functions via a direct numerical solution of the TLGFs. SDEAM is robust and error-controllable as it can take advantage of well-established and reliable numerical methods to solve the boundary value problems (BVPs) governing TLGFs, and can utilize high-order basis functions and discretization refinement to achieve error control.

The method may further include the use of SDEAM which further includes:
(i) expressing the mixed potential Green's functions in terms of TLGFs defined as one dimensional (1D) boundary value problems (BVPs) where each BVP consists of an differential equation (DE), boundary conditions (BCs) at layer interfaces and BCs at top and bottom boundaries;
(ii) casting a 1D BVP numerically into a system of linear algebraic equations (SLAE) in the form of

(A^{X}+k_{ρ}²B^{X})X=b (9)
where A^{X} and B^{X} are known invertible matrices, X is the vector holding some unknown TLGF coefficients at discretization nodes, b is a known vector of excitation;
(iii) performing matrix decomposition E^{X}D^{X}(E^{X})⁻¹=(B^{X})⁻¹A^{X} where D^{X} is a diagonal matrix;
(iv) representing the solution to the SLAE in a pole-residue form

X=E^{X}(D^{X}+k_{ρ}²I)⁻¹T^{X}b (10)
where T^{X}=(B^{X}E^{X})⁻¹;
(v) analytically evaluating pertinent inverse Fourier transform integrals with the integrands involving X defined in the pole-residue form.

The method may further include its usage in either a 2.5D or fully 3D electromagnetic analysis, in which Kₓₓ^{A} and G^{Φ} mixed potential Green's function components are necessary, the method further comprising: defining the 1D BVPs for TLGFs voltages Vᵢ^{h} and Vᵢ^{e}, in which the differential equation of Vᵢ^{h} is defined as

$$\frac{{d}^{2} {V}_{i}^{h}}{{dz}^{2}} + ( {k}_{t}^{2} - {v}^{h} {k}_{ρ}^{2} ) {V}_{i}^{h} = - j ω {μ}_{0} {μ}_{t} δ ( z - {z}^{′} ) , \qquad ( 11 )$$

and the boundary conditions at layer interfaces are defined as

$${V}_{i}^{h} {\vert}_{{z}_{int}^{-}} = {V}_{i}^{h} {\vert}_{{z}_{int}^{+}} , ( \frac{1}{{μ}_{t}} \frac{{dV}_{i}^{h}}{dz} ) {\vert}_{{z}_{int}^{-}} = ( \frac{1}{{μ}_{t}} \frac{{dV}_{i}^{h}}{dz} ) {\vert}_{{z}_{int}^{+}} , \qquad ( 12 )$$

and if the medium is fully shielded, defining the boundary conditions at top and bottom perfect electric conductor (PEC) ground plates as

$${V}_{i}^{h} {\vert}_{{z}_{g}^{b}} = 0 , {V}_{i}^{h} {\vert}_{{z}_{g}^{t}} = 0 \qquad ( 13 )$$

if the medium partially open on top, defining the boundary conditions at bottom PEC ground plate and top truncation boundary as

$${V}_{i}^{h} {\vert}_{{z}_{g}^{b}} = 0 , \frac{{dV}_{i}^{h}}{dz} {\vert}_{{z}^{t}} + j \sqrt{{k}_{0}^{2} - {k}_{ρ}^{2}} {V}_{i}^{h} {\vert}_{{z}^{t}} = 0 , \qquad ( 14 )$$

if the medium is partially open on bottom, defining the boundary conditions at bottom truncation boundary and top PEC ground plate as

$$\frac{{dV}_{i}^{h}}{dz} {\vert}_{{z}^{b}} + j \sqrt{{k}_{0}^{2} - {k}_{ρ}^{2}} {V}_{i}^{h} {\vert}_{{z}^{b}} = 0 , {V}_{i}^{h} {\vert}_{{z}_{g}^{t}} = 0 , \qquad ( 15 )$$

if the medium is fully open, defining the boundary conditions at top and bottom truncation boundaries as

$$\frac{{dV}_{i}^{h}}{dz} {\vert}_{{z}^{b}} - j \sqrt{{k}_{0}^{2} - {k}_{ρ}^{2}} {V}_{i}^{h} {\vert}_{{z}^{b}} = 0 , \\ \frac{{dV}_{i}^{h}}{dz} {\vert}_{{z}^{t}} + j \sqrt{{k}_{0}^{2} - {k}_{ρ}^{2}} {V}_{i}^{h} {\vert}_{{z}^{t}} = 0 , \qquad ( 16 )$$

and the BVP of Vᵢ^{e} consisting of the differential equation defined as

$$\frac{{d}^{2} {V}_{i}^{e}}{{dz}^{2}} + ( {k}_{t}^{2} - {v}^{e} {k}_{ρ}^{2} ) {V}_{i}^{e} = - j \frac{{k}_{t}^{2} - {k}_{ρ}^{2}}{{ωε}_{0} {ε}_{t}} δ ( z - {z}^{′} ) , \qquad ( 17 )$$

boundary conditions at layer interfaces defined as

$${V}_{i}^{e} {\vert}_{{z}_{int}^{-}} = {V}_{i}^{e} {\vert}_{{z}_{int}^{+}} , ( \frac{{ωε}_{0} {ε}_{t}}{{k}_{t}^{2} - {k}_{ρ}^{2}} \frac{{dV}_{i}^{e}}{dz} ) {\vert}_{{z}_{int}^{-}} = ( \frac{{ωε}_{0} {ε}_{t}}{{k}_{t}^{2} - {k}_{ρ}^{2}} \frac{{dV}_{i}^{e}}{dz} ) {\vert}_{{z}_{int}^{+}} , \qquad ( 18 )$$

and if the medium is fully shielded, defining the boundary conditions at top and bottom PEC ground plates as

$${V}_{i}^{e} {\vert}_{{z}_{g}^{b}} = 0 , {V}_{i}^{e} {\vert}_{{z}_{g}^{t}} = 0 , \qquad ( 19 )$$

if the medium is partially open on top, defining the boundary conditions at bottom PEC plate and top truncation boundary as

$${V}_{i}^{e} {\vert}_{{z}_{g}^{b}} = 0 , \frac{{dV}_{i}^{e}}{dz} {\vert}_{{z}^{t}} + j \sqrt{{k}_{0}^{2} - {k}_{ρ}^{2}} {V}_{i}^{e} {\vert}_{{z}^{t}} = 0 , \qquad ( 20 )$$

if the medium is partially open on bottom, defining the boundary conditions at bottom truncation boundary and top PEC plate as

$$\frac{{dV}_{i}^{e}}{dz} {\vert}_{{z}^{b}} - j \sqrt{{k}_{0}^{2} - {k}_{ρ}^{2}} {V}_{i}^{e} {\vert}_{{z}^{b}} = 0 , {V}_{i}^{e} {\vert}_{{z}_{g}^{t}} = 0 , \qquad ( 21 )$$

if the medium is fully open, defining the boundary conditions at top and bottom truncation boundaries as

$$\frac{{dV}_{i}^{e}}{dz} {\vert}_{{z}^{b}} - j \sqrt{{k}_{0}^{2} - {k}_{ρ}^{2}} {V}_{i}^{e} {\vert}_{{z}^{b}} = 0 , \\ \frac{{dV}_{i}^{e}}{dz} {\vert}_{{z}^{t}} + j \sqrt{{k}_{0}^{2} - {k}_{ρ}^{2}} {V}_{i}^{e} {\vert}_{{z}^{t}} = 0 , \qquad ( 22 )$$

with expressing the elevation of an dielectric layer interface of the layered medium as zᵢₙₜ, the elevations of the bottom and top PEC ground plates as z_{g}^{b} and z_{g}^{t} respectively, the elevations of the bottom and top truncation boundaries as z^{b} and z^{t} respectively.

The method may further include transforming the BVP of Vᵢ^{e} to such DE

$$\frac{{d}^{2} {\hat{V}}_{i}^{e}}{{dz}^{2}} + ( {k}_{t}^{2} - {v}^{e} {k}_{ρ}^{2} ) {\hat{V}}_{i}^{e} = - j δ ( z - {z}^{′} ) , \qquad ( 23 )$$

boundary conditions at layer interfaces

$$( \frac{{k}_{t}^{2} - {v}^{e} {k}_{ρ}^{2}}{{ωε}_{0} {ε}_{t}} {\hat{V}}_{i}^{e} ) {\vert}_{{z}_{int}^{-}} = ( \frac{{k}_{t}^{2} - {v}^{e} {k}_{ρ}^{2}}{{ωε}_{0} {ε}_{t}} {\hat{V}}_{i}^{e} ) {\vert}_{{z}_{int}^{+}} , \\ ( \frac{d {\hat{V}}_{i}^{e}}{dz} ) {\vert}_{{z}_{int}^{-}} = ( \frac{d {\hat{V}}_{i}^{e}}{dz} ) {\vert}_{{z}_{int}^{+}} , \qquad ( 24 )$$

and if the medium is fully shielded, defining the boundary conditions at top and bottom PEC ground plates as

$${\hat{V}}_{i}^{e} {\vert}_{{z}_{g}^{b}} = 0 , {\hat{V}}_{i}^{e} {\vert}_{{z}_{g}^{t}} = 0 , \qquad ( 25 )$$

if the medium is partially open on top, defining the boundary conditions at bottom PEC plate and top truncation boundary as

$${\hat{V}}_{i}^{e} {\vert}_{{z}_{g}^{b}} = 0 , \frac{d {\hat{V}}_{i}^{e}}{dz} {\vert}_{{z}^{t}} + j \sqrt{{k}_{0}^{2} - {k}_{ρ}^{2}} {\hat{V}}_{i}^{e} {\vert}_{{z}^{t}} = 0 , \qquad ( 26 )$$

if the medium is partially open on bottom, defining the boundary conditions at bottom truncation boundary and top PEC plate as

$$\frac{d {\hat{V}}_{i}^{e}}{dz} {\vert}_{{z}^{b}} - j \sqrt{{k}_{0}^{2} - {k}_{ρ}^{2}} {\hat{V}}_{i}^{e} {\vert}_{{z}^{b}} = 0 , {\hat{V}}_{i}^{e} {\vert}_{{z}_{g}^{t}} = 0 , \qquad ( 27 )$$

if the medium is fully open, defining the boundary conditions at top and bottom truncation boundaries as

$$\frac{d {\hat{V}}_{i}^{e}}{dz} {\vert}_{{z}^{b}} - j \sqrt{{k}_{0}^{2} - {k}_{ρ}^{2}} {\hat{V}}_{i}^{e} {\vert}_{{z}^{b}} = 0 , \\ \frac{d {\hat{V}}_{i}^{e}}{dz} {\vert}_{{z}^{t}} + j \sqrt{{k}_{0}^{2} - {k}_{ρ}^{2}} {\hat{V}}_{i}^{e} {\vert}_{{z}^{t}} = 0 , \qquad ( 28 )$$

with the transform defined as

$${\hat{V}}_{i}^{e} = \frac{{ωε}_{0} {ε}_{t}}{{k}_{t}^{2} - {v}^{e} {k}_{ρ}^{2}} {V}_{i}^{e} \qquad ( 29 )$$

to benefit subsequent pole residue representation of Vᵢ^{e}.

The method may further include, when the medium is not fully shielded such that the medium is partially open on bottom, partially open on top, or fully open: representing the square root in a radiation boundary condition (RBC) as

$$\frac{1}{\sqrt{{k}_{0}^{2} - {k}_{ρ}^{2}}} ≅ {\sum }_{p = 1}^{P - 1} \frac{{C}_{p}}{{k}_{ρ}^{2} - {α}_{p}} + {C}_{0} \qquad ( 30 )$$

where Cₚ are known coefficients, αₚ are known poles generated by the VECTFIT algorithm, introducing auxiliary variables

$${E}_{p} = \frac{{C}_{p}}{{k}_{ρ}^{2} - {α}_{p}} \frac{dV}{dz} {\vert}_{{z}_{bdry}} , p = 1 , 2 , … , P \qquad ( 31 )$$

with z_{bdry} being the truncated open boundary to the corresponding SLAE where V can be Vᵢ^{h} or \hat{V}ᵢ^{e} in order to combine the ODE and RBC at the open medium boundary truncation while still enabling pole residue representations of Vᵢ^{h} and Vᵢ^{e}.

The method may further include representing the pole residue expressions of Vᵢ^{h} and Vᵢ^{e} at the nth discretization node as

$${V}_{i , n}^{h} = {\sum }_{s ∈ S} {b}_{s}^{{V}_{i}^{h}} {\sum }_{m = 1}^{{N}_{c}} \frac{{E}_{nm}^{{V}_{i}^{h}} {T}_{ms}^{{V}_{i}^{h}}}{{D}_{mm}^{{V}_{i}^{h}} + {k}_{ρ}^{2}} , \qquad ( 32 )$$

$${V}_{i , n}^{e} = \frac{{k}_{t , n}^{2}}{ω {ε}_{0} {ε}_{t , n}} {\sum }_{s ∈ S} {b}_{s}^{{\hat{V}}_{i}^{e}} {\sum }_{m = 1}^{{N}_{d}} \frac{{E}_{nm}^{{\hat{V}}_{i}^{e}} {T}_{ms}^{{\hat{V}}_{i}^{e}}}{{D}_{mm}^{{\hat{V}}_{i}^{e}} + {k}_{ρ}^{2}} - \frac{{v}_{n}^{e}}{ω {ε}_{0} {ε}_{t , n}} {\sum }_{s ∈ S} {b}_{s}^{{\hat{V}}_{i}^{e}} {\sum }_{m = 1}^{{N}_{d}} \frac{{E}_{nm}^{{\hat{V}}_{i}^{e}} {T}_{ms}^{{\hat{V}}_{i}^{e}} {k}_{ρ}^{2}}{{D}_{mm}^{{\hat{V}}_{i}^{e}} + {k}_{ρ}^{2}} , \qquad ( 33 )$$

with the set S containing the non-zero entries of the RHS vector b, N_{c} and N_{d} being the size of the SLAE of Vᵢ^{h} and \hat{V}ᵢ^{e} respectively.

The method may further include performing the analytical inverse Fourier transform on \tilde{K}ₓₓ^{A} and \tilde{G}^{Φ}, which leads to spatial domain closed form summation

$${K}_{xx , n}^{A} = \frac{1}{2 π j ω {μ}_{0}} {\sum }_{s ∈ S} {b}_{s}^{{V}_{i}^{h}} {\sum }_{m = 1}^{{N}_{c}} {E}_{nm}^{{V}_{i}^{h}} {T}_{ms}^{{V}_{i}^{h}} {η}_{1} ( {D}_{mm}^{{V}_{i}^{h}} , ρ ) \qquad ( 34 )$$

$${G}_{n}^{Φ} = \frac{j}{2 π} [ ( \frac{{k}_{t , n}^{2}}{{ε}_{t , n}} ) {\sum }_{s ∈ S} {b}_{s}^{{\hat{V}}_{i}^{e}} {\sum }_{m = 1}^{{N}_{c}} {E}_{nm}^{{\hat{V}}_{i}^{e}} {T}_{ms}^{{\hat{V}}_{i}^{e}} {η}_{3} ( {D}_{mm}^{{\hat{V}}_{i}^{e}} , ρ ) - \qquad ( 35 )$$

$$\frac{{V}_{e , n}}{{ε}_{t , n}} {\sum }_{s ∈ S} {b}_{s}^{{\hat{V}}_{i}^{e}} {\sum }_{m = 1}^{{N}_{c}} {E}_{nm}^{{\hat{V}}_{i}^{e}} {T}_{ms}^{{\hat{V}}_{i}^{e}} {η}_{1} ( {D}_{mm}^{{\hat{V}}_{i}^{e}} , ρ ) - ω {ε}_{0} {\sum }_{s ∈ S} {b}_{s}^{{V}_{i}^{h}} {\sum }_{m = 1}^{{N}_{d}} {E}_{nm}^{{V}_{i}^{h}} {T}_{ms}^{{V}_{i}^{h}} {η}_{3} ( {D}_{mm}^{{V}_{i}^{h}} , ρ ) ]$$

wherein the functions η₁, and η₃ are

$${η}_{1} ( {D}_{mm} , ρ ) = - \frac{π j}{2} {H}_{0}^{( 2 )} ( - j \sqrt{{D}_{mm}} ρ ) \qquad ( 36 )$$

$${η}_{3} ( {D}_{mm} , ρ ) = \frac{π j}{2 {D}_{mm}} {H}_{0}^{( 2 )} ( - j \sqrt{{D}_{mm}} ρ ) . \qquad ( 37 )$$

The method may further include its usage in a shielded full 3D electromagnetic analysis problem, in which all components of mixed potential Green's functions \tilde{K}^{A} and G^{Φ} are needed, the method further comprising: defining 1D BVPs for currents Iᵥ^{e} and Iᵥ^{h}, in which the BVP of Iᵥ^{e} contains the DE

$$\frac{{d}^{2} {I}_{v}^{e}}{{dz}^{2}} + ( {k}_{t}^{2} - {v}^{e} {k}_{ρ}^{2} ) {I}_{v}^{e} = - j ω {ε}_{0} {ε}_{t} δ ( z - {z}^{′} ) , \qquad ( 38 )$$

boundary conditions at layer interfaces

$$( \frac{1}{{ε}_{t}} \frac{{dI}_{v}^{e}}{dz} ) {\vert}_{{z}_{int}^{-}} = ( \frac{1}{{ε}_{t}} \frac{{dI}_{v}^{e}}{dz} ) {\vert}_{{z}_{int}^{+}} , {I}_{v}^{e} {\vert}_{{z}_{int}^{-}} = {I}_{v}^{e} {\vert}_{{z}_{int}^{+}} , \qquad ( 39 )$$

and if the medium is fully shielded, defining the boundary conditions at top and bottom PEC ground plates as

$$\frac{{dI}_{v}^{e}}{dz} {\vert}_{{z}_{g}^{b}} = 0 , \frac{{dI}_{v}^{e}}{dz} {\vert}_{{z}_{g}^{t}} = 0 , \qquad ( 40 )$$

if the medium is partially open on top, defining the boundary conditions at bottom PEC plate and top truncation boundary as

$$\frac{{dI}_{v}^{e}}{dz} {\vert}_{{z}_{g}^{b}} = 0 , \frac{{dI}_{v}^{e}}{dz} {\vert}_{{z}^{t}} + j \sqrt{{k}_{0}^{2} - {k}_{ρ}^{2}} {I}_{v}^{e} {\vert}_{{z}^{t}} = 0 , \qquad ( 41 )$$

if the medium is partially open on bottom, defining the boundary conditions at bottom truncation boundary and top PEC plate as

$$\frac{{dI}_{v}^{e}}{dz} {\vert}_{{z}^{b}} - j \sqrt{{k}_{0}^{2} - {k}_{ρ}^{2}} {I}_{v}^{e} {\vert}_{{z}^{b}} = 0 , \frac{{dI}_{v}^{e}}{dz} {\vert}_{{z}_{g}^{t}} = 0 , \qquad ( 42 )$$

if the medium is fully open, defining the boundary conditions at top and bottom truncation boundaries as

$$\frac{{dI}_{v}^{e}}{dz} {\vert}_{{z}^{b}} - j \sqrt{{k}_{0}^{2} - {k}_{ρ}^{2}} {I}_{v}^{e} {\vert}_{{z}^{b}} = 0 , \frac{{dI}_{v}^{e}}{dz} {\vert}_{{z}^{t}} + j \sqrt{{k}_{0}^{2} - {k}_{ρ}^{2}} {I}_{v}^{e} {\vert}_{{z}^{t}} = 0 , \qquad ( 43 )$$

and defining the BVP of Iᵥ^{h} containing DE

$$\frac{{d}^{2} {I}_{v}^{h}}{{dz}^{2}} + ( {k}_{t}^{2} - {v}^{h} {k}_{ρ}^{2} ) {I}_{v}^{h} = - j \frac{{k}_{t}^{2} - {k}_{ρ}^{2}}{ω {ε}_{0} {ε}_{t}} δ ( z - {z}^{′} ) , \qquad ( 44 )$$

boundary conditions at layer interfaces

$${I}_{v}^{h} {\vert}_{{z}_{int}^{-}} = {I}_{v}^{h} {\vert}_{{z}_{int}^{+}} , ( \frac{ω {μ}_{0} {μ}_{t}}{{k}_{t}^{2} - {k}_{ρ}^{2}} \frac{{dI}_{v}^{h}}{dz} ) {\vert}_{{z}_{int}^{-}} = ( \frac{ω {μ}_{0} {μ}_{t}}{{k}_{t}^{2} - {k}_{ρ}^{2}} \frac{{dI}_{v}^{h}}{dz} ) {\vert}_{{z}_{int}^{+}} , \qquad ( 45 )$$

and if the medium is fully shielded, defining the boundary conditions at top and bottom PEC ground plates as

$$\frac{{dI}_{v}^{h}}{dz} {\vert}_{{z}_{g}^{b}} = 0 , \frac{{dI}_{v}^{h}}{dz} {\vert}_{{z}_{g}^{t}} = 0 , \qquad ( 46 )$$

if the medium is partially open on top, defining the boundary conditions at bottom PEC plate and top truncation boundary as

$$\frac{{dI}_{v}^{h}}{dz} {\vert}_{{z}_{g}^{b}} = 0 , \frac{{dI}_{v}^{h}}{dz} {\vert}_{{z}^{t}} + j \sqrt{{k}_{0}^{2} - {k}_{ρ}^{2}} {I}_{v}^{h} {\vert}_{{z}^{t}} = 0 , \qquad ( 47 )$$

if the medium is partially open on bottom, defining the boundary conditions at bottom truncation boundary and top PEC plate as

$$\frac{{dI}_{v}^{h}}{dz} {\vert}_{{z}^{b}} - j \sqrt{{k}_{0}^{2} - {k}_{ρ}^{2}} {I}_{v}^{h} {\vert}_{{z}^{b}} = 0 , \frac{{dI}_{v}^{h}}{dz} {\vert}_{{z}_{g}^{t}} = 0 , \qquad ( 48 )$$

if the medium is fully open, defining the boundary conditions at top and bottom truncation boundaries as

$$\frac{{dI}_{v}^{h}}{dz} {\vert}_{{z}^{b}} - j \sqrt{{k}_{0}^{2} - {k}_{ρ}^{2}} {I}_{v}^{h} {\vert}_{{z}^{b}} = 0 , \frac{{dI}_{v}^{h}}{dz} {\vert}_{{z}^{t}} + j \sqrt{{k}_{0}^{2} - {k}_{ρ}^{2}} {I}_{v}^{h} {\vert}_{{z}^{t}} = 0. \qquad ( 49 )$$

The method may further include transforming the BVP of Iᵥ^{h} to such DE

$$\frac{{d}^{2} {\hat{I}}_{v}^{h}}{{dz}^{2}} + ( {k}_{t}^{2} - {v}^{h} {k}_{ρ}^{2} ) {\hat{I}}_{v}^{h} = - j δ ( z - {z}^{′} ) , \qquad ( 50 )$$

boundary conditions at layer interfaces

$$( \frac{{k}_{t}^{2} - {v}^{h} {k}_{ρ}^{2}}{{ωμ}_{0} {μ}_{t}} {\hat{I}}_{v}^{h} ) {\vert}_{{z}_{int}^{-}} = ( \frac{{k}_{t}^{2} - {v}^{h} {k}_{ρ}^{2}}{{ωμ}_{0} {μ}_{t}} {\hat{I}}_{v}^{h} ) {\vert}_{{z}_{int}^{+}} , \\ ( \frac{d {\hat{I}}_{v}^{h}}{dz} ) {\vert}_{{z}_{int}^{-}} = ( \frac{d {\hat{I}}_{v}^{h}}{dz} ) {\vert}_{{z}_{int}^{+}} , \qquad ( 51 )$$

and if the medium is fully shielded, defining the boundary conditions at top and bottom PEC ground plates as

$$\frac{d {\hat{I}}_{v}^{h}}{dz} {\vert}_{{z}_{g}^{b}} = 0 , \frac{d {\hat{I}}_{v}^{h}}{dz} {\vert}_{{z}_{g}^{t}} = 0 , \qquad ( 52 )$$

if the medium is partially open on top, defining the boundary conditions at bottom PEC plate and top truncation boundary as

$$\frac{d {\hat{I}}_{v}^{h}}{dz} {\vert}_{{z}_{g}^{b}} = 0 , \frac{d {\hat{I}}_{v}^{h}}{dz} {\vert}_{{z}^{t}} + j \sqrt{{k}_{0}^{2} - {k}_{ρ}^{2}} {\hat{I}}_{v}^{h} {\vert}_{{z}^{t}} = 0 , \qquad ( 53 )$$

if the medium is partially open on bottom, defining the boundary conditions at bottom truncation boundary and top PEC plate as

$$\frac{d {\hat{I}}_{v}^{h}}{dz} {\vert}_{{z}^{b}} - j \sqrt{{k}_{0}^{2} - {k}_{ρ}^{2}} {\hat{I}}_{v}^{h} {\vert}_{{z}^{b}} = 0 , \frac{d {\hat{I}}_{v}^{h}}{dz} {\vert}_{{z}_{g}^{t}} = 0 , \qquad ( 54 )$$

if the medium is fully open, defining the boundary conditions at top and bottom truncation boundaries as

$$\frac{d {\hat{I}}_{v}^{h}}{dz} {\vert}_{{z}^{b}} - j \sqrt{{k}_{0}^{2} - {k}_{ρ}^{2}} {\hat{I}}_{v}^{h} {\vert}_{{z}^{b}} = 0 , \frac{d {\hat{I}}_{v}^{h}}{dz} {\vert}_{{z}^{t}} + j \sqrt{{k}_{0}^{2} - {k}_{ρ}^{2}} {\hat{I}}_{v}^{h} {\vert}_{{z}^{t}} = 0. \qquad ( 55 )$$

with the transform defined as

$${\hat{I}}_{v}^{h} = \frac{{ωμ}_{0} {μ}_{t}}{{k}_{t}^{2} - {v}^{h} {k}_{ρ}^{2}} {I}_{v}^{h} , \qquad ( 56 )$$

to benefit the pole residue representation of Iᵥ^{h}.

The method may further include, if/when the medium is not fully shielded such that the medium is partially open on bottom, partially open on top, or fully open: representing the square root in a radiation boundary condition (RBC) as

$$\frac{1}{\sqrt{{k}_{0}^{2} - {k}_{ρ}^{2}}} ≅ {\sum }_{p = 1}^{P - 1} \frac{{C}_{p}}{{k}_{ρ}^{2} - {α}_{p}} + {C}_{0} \qquad ( 57 )$$

where Cₚ are known coefficients, αₚ are known poles generated by the VECTFIT algorithm, introducing auxiliary variables

$${E}_{p} = \frac{{C}_{p}}{{k}_{ρ}^{2} - {α}_{p}} \frac{dI}{dz} {\vert}_{{z}_{bdry}} , p = 1 , 2 , ⋯ , P \qquad ( 58 )$$

with z_{bdry} being the truncated open boundary to the corresponding SLAE where I can be Iᵥ^{e} or Îᵥ^{h} in order to combine the ODE and RBC at the open medium boundary truncation while still enabling pole residue representations of Iᵥ^{e} and Iᵥ^{h}.

The method may further include formulating pole-residue expressions of TLGFs Iᵥ^{h} and Iᵥ^{e} as

$${I}_{v , n}^{h} = \frac{{k}_{t , n}^{2}}{{ωμ}_{0} {μ}_{t , n}} {\sum }_{s ∈ S} {b}_{s}^{{\hat{I}}_{v}^{h}} {\sum }_{m = 1}^{{N}_{d}} \frac{{E}_{nm}^{{\hat{I}}_{v}^{h}} {T}_{ms}^{{\hat{I}}_{v}^{h}}}{{D}_{mm}^{{\hat{I}}_{v}^{h}} + {k}_{ρ}^{2}} - \frac{{v}_{n}^{h}}{{ωμ}_{0} {μ}_{t , n}} {\sum }_{s ∈ S} {b}_{s}^{{\hat{I}}_{v}^{h}} {\sum }_{m = 1}^{{N}_{d}} \frac{{E}_{nm}^{{\hat{I}}_{v}^{h}} {T}_{ms}^{{\hat{I}}_{v}^{h}} {k}_{ρ}^{2}}{{D}_{mm}^{{\hat{I}}_{v}^{h}} + {k}_{ρ}^{2}} , \qquad ( 59 )$$

$${I}_{v , n}^{e} = {\sum }_{s ∈ S} {b}_{s}^{{I}_{v}^{e}} {\sum }_{m = 1}^{{N}_{c}} \frac{{E}_{nm}^{{I}_{v}^{e}} {T}_{ms}^{{I}_{v}^{e}}}{{D}_{mm}^{{I}_{v}^{e}} + {k}_{ρ}^{2}} . \qquad ( 60 )$$

The method may further include, subsequent to obtaining the pole-residue representations of Vᵢ^{h}, Vᵢ^{e}, Iᵥ^{e}, and Iᵥ^{h}, taking each of their derivatives to obtain the pole-residue forms of TLGFs Iᵢ^{h}, Iᵢ^{e}, Vᵥ^{e}, and Vᵥ^{h}.

The method may further include using high--order numerical methods for solving the TLGEs of Vᵢ^{h}, Vᵢ^{e}, Iᵥ^{e}, and Iᵥ^{h} and taking the derivatives of the results, which leads to pole-residue forms of Iᵢ^{h}, Iᵢ^{e}, Vᵥ^{e}, and Vᵥ^{h} as

$${I}_{i , n}^{h} = \frac{j}{{ωμ}_{0} {μ}_{t}^{{k}_{n}}} {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{V}_{i}^{h}} {\sum }_{m = 1}^{{N}_{c}} \frac{{E}_{{n}_{q}^{{k}_{n}} m}^{{V}_{i}^{h}} {T}_{ms}^{{V}_{i}^{h}}}{{D}_{mm}^{{V}_{i}^{h}} + {k}_{ρ}^{2}} \qquad ( 61 )$$

$${I}_{i , n}^{e} = j {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{\hat{V}}_{i}^{e}} {\sum }_{m = 1}^{{N}_{d}} \frac{{E}_{{n}_{q}^{{k}_{n}} m}^{{\hat{V}}_{i}^{e}} {T}_{ms}^{{\hat{V}}_{i}^{e}}}{{D}_{mm}^{{\hat{V}}_{i}^{e}} + {k}_{ρ}^{2}} \qquad ( 62 )$$

$${V}_{v , n}^{e} = \frac{j}{{ωε}_{0} {ε}_{t}^{{k}_{n}}} {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{I}_{v}^{e}} {\sum }_{m = 1}^{{N}_{c}} \frac{{E}_{{n}_{q}^{{k}_{n}} m}^{{I}_{v}^{e}} {T}_{ms}^{{I}_{v}^{e}}}{{D}_{mm}^{{I}_{v}^{e}} + {k}_{ρ}^{2}} \qquad ( 63 )$$

$${V}_{v , n}^{h} = j {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{\hat{I}}_{v}^{h}} {\sum }_{m = 1}^{{N}_{d}} \frac{{E}_{{n}_{q}^{{k}_{n}} m}^{{\hat{I}}_{v}^{h}} {T}_{ms}^{{\hat{I}}_{v}^{h}}}{{D}_{mm}^{{\hat{I}}_{v}^{h}} + {k}_{ρ}^{2}} \qquad ( 64 )$$

where kₙ being the index of the element that contains the nth discretization node.

The method may further include formulating components K_{xz}^{A}, K_{yz}^{A}, and K_{zz}^{A} of the dyadic Green's function K̅^{A} in the spatial domain through the evaluation of the inverse Fourier transform as

$$\{ \begin{matrix}{K}_{xz , n}^{A} \\ {K}_{yz , n}^{A}\end{matrix} \} = \{ \begin{matrix}cos α \\ sin α\end{matrix} \} ( \frac{j {μ}_{t}^{′}}{2 {πωε}_{0} {ε}_{t}^{{k}_{n}}} {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{I}_{v}^{e}} {\sum }_{m = 1}^{{N}_{c}} {E}_{{n}_{q}^{{k}_{n}} m}^{{I}_{v}^{e}} {T}_{ms}^{{I}_{v}^{e}} {η}_{2} ( {D}_{mm}^{{I}_{v}^{e}} , ρ ) - \frac{j {μ}_{t}^{′}}{2 π} {\sum }_{q = 1}^{{N}^{{k}_{n}}} {( {l}_{q}^{{k}_{n}} )}^{′} {\vert}_{{z}_{n}} {\sum }_{s ∈ S} {b}_{s}^{{\hat{I}}_{v}^{h}} {\sum }_{m = 1}^{{N}_{d}} {E}_{{n}_{q}^{{k}_{n}} m}^{{\hat{I}}_{v}^{h}} {T}_{ms}^{{\hat{I}}_{v}^{h}} {η}_{2} ( {D}_{mm}^{{\hat{I}}_{v}^{h}} , ρ ) ) \qquad ( 65 )$$

$${K}_{zz , n}^{A} = \frac{1}{2 π j {ωμ}_{0}} [ ( \frac{{μ}_{t}^{{k}_{n}}}{{ε}_{z}^{′}} + {v}_{e}^{{k}_{n}} \frac{{μ}_{t}^{′}}{{ε}_{t}^{{k}_{n}}} ) {\sum }_{s ∈ S} {b}_{s}^{{I}_{v}^{e}} {\sum }_{m = 1}^{{N}_{c}} {E}_{nm}^{{I}_{v}^{e}} {T}_{ms}^{{I}_{v}^{e}} {η}_{1} ( {D}_{mm}^{{I}_{v}^{e}} , ρ ) - \frac{{( {k}_{t}^{2} )}^{{k}_{n}} {μ}_{t}^{′}}{{ε}_{t}^{{k}_{n}}} {\sum }_{s ∈ S} {b}_{s}^{{I}_{v}^{e}} {\sum }_{m = 1}^{{N}_{c}} {E}_{nm}^{{I}_{v}^{e}} {T}_{ms}^{{I}_{v}^{e}} {η}_{3} ( {D}_{mm}^{{I}_{v}^{e}} , ρ ) + {ωε}_{0} {{μ}_{t}^{′} ( {k}_{t}^{2} )}^{{k}_{n}} {\sum }_{s ∈ S} {b}_{s}^{{\hat{I}}_{v}^{h}} {\sum }_{m = 1}^{{N}_{d}} {E}_{nm}^{{\hat{I}}_{v}^{h}} {T}_{ms}^{{\hat{I}}_{v}^{h}} {η}_{3} ( {D}_{mm}^{{\hat{I}}_{v}^{h}} , ρ ) - {ωε}_{0} {{μ}_{t}^{′} ( {v}^{h} )}^{{k}_{n}} {\sum }_{s ∈ S} {b}_{s}^{{\hat{I}}_{v}^{h}} {\sum }_{m = 1}^{{N}_{d}} {E}_{nm}^{{\hat{I}}_{v}^{h}} {T}_{ms}^{{\hat{I}}_{v}^{h}} {η}_{1} ( {D}_{mm}^{{\hat{I}}_{v}^{h}} , ρ ) ] \qquad ( 66 )$$

$$where$$

$${η}_{2} ( {D}_{mm} , ρ ) = \frac{π}{2 \sqrt{{D}_{mm}}} {H}_{1}^{( 2 )} ( - j \sqrt{{D}_{mm}} ρ ) . \qquad ( 67 )$$

The method may further include obtaining components K_{zx}^{A} and K_{zy}^{A} from reciprocity relationships

$${K}_{zx}^{A} ( ρ , {z}^{′} \vert z ) = - \frac{{μ}_{t}}{{μ}_{t}^{′}} {K}_{xz}^{A} ( ρ , z \vert {z}^{′} ) , \qquad ( 68 )$$

$${K}_{zy}^{A} ( ρ , {z}^{′} \vert z ) = - \frac{{μ}_{t}}{{μ}_{t}^{′}} {K}_{yz}^{A} ( ρ , z \vert {z}^{′} ) . \qquad ( 69 )$$

In one application of the invention, the conductive elements comprise interconnects within a circuit assembly and the yered medium comprises stratified layers of the circuit assembly. In this instance, the method includes solving for electric current in the circuit assembly.

In another application of the invention, the conductive ounding element comprises a structural metal frame embedded within a concrete foundation structure and the multilayered medium comprises layers of foundation materials within the foundation structure. In this instance, the method includes solving for electric current in both the conductive grounding elements and the concrete foundation structure.

In another application of the invention, the dielectric elements comprise optical interconnects within an integrated photonics assembly the multilayered medium comprises stratified layers of the photonics assembly. In this instance, the method includes solving for electric and magnetic currents in the photonics assembly.

In another application of the invention, the dielectric elements comprise underground natural resource formations within the layers of soil and the multilayered medium comprises layers of Earth strata. In this instance,the method includes solving for electric and magnetic currents in the natural resource formations.

In another application of the invention, the dielectric elements comprise sea ice formations within the ocean ice sheets and the multilayered medium comprises layers of sea ice, water, and snow. In this instance, the method includes solving for electric and magnetic currents in the natural and man-made irregularities present in the layers.

### BRIEF DESCRIPTION OF THE SEVERAL VIEWS OF THE DRAWINGS

FIG. 1 is the layered-medium structure: (a) fully shielded planar L-layer medium, (b) planar L-layer medium partially open on bottom, (c) planar L-layer medium partially open on bottom, (d) fully open planar L-layer medium.

FIG. 2 is a fully shielded radio frequency integrated circuit (RFIC) model.

FIG. 3 is the comparison of [symbol] (Kₓₓ^{A}) and [symbol] (Kₓₓ^{A}) between SDEAM and Discrete Complex Image Method (DCIM) for two fixed ρ samples.

FIG. 4 is the comparison of the magnitude and phase of Kₓₓ^{A} between SDEAM and DCIM for two fixed z samples.

FIG. 5 is the comparison of [symbol] (K_{xz}^{A}) and [symbol] (K_{xz}^{A}) between SDEAM and DCIM for two fixed ρ samples.

FIG. 6 is the comparison of the magnitude and phase of K_{xz}^{A} between SDEAM and DCIM for two fixed z samples.

FIG. 7 is the comparison of [symbol] (K_{zz}^{A}) and [symbol] (K_{zz}^{A}) between SDEAM and DCIM for two fixed ρ samples.

FIG. 8 is the comparison of the magnitude and phase of K_{zz}^{A} between SDEAM and DCIM for two fixed z samples.

FIG. 9 is the comparison of [symbol] (G^{Φ}) and [symbol] (G^{Φ}) between SDEAM and DCIM for two fixed ρ samples.

FIG. 10 is the comparison of the magnitude and phase of G^{Φ} between SDEAM and DCIM for two fixed z samples.

FIG. 11 is the relative absolute error of SDEAM- and DCIM-generated Kₓₓ^{A} results compared to weighted average (WA) result for two fixed ρ samples.

FIG. 12 is the relative absolute error of SDEAM- and DCIM-generated Kₓₓ^{A} results compared to WA result for two fixed z samples.

FIG. 13 is the comparison between finite-difference method based SDEAM (in solid lines) and DCIM (in dashed lines) generated Kₓₓ^{A} and K^{Φ}=G^{Φ} mixed potential Green's functions versus radial coordinate ρ.

### DETAILED DESCRIPTION OF THE INVENTION

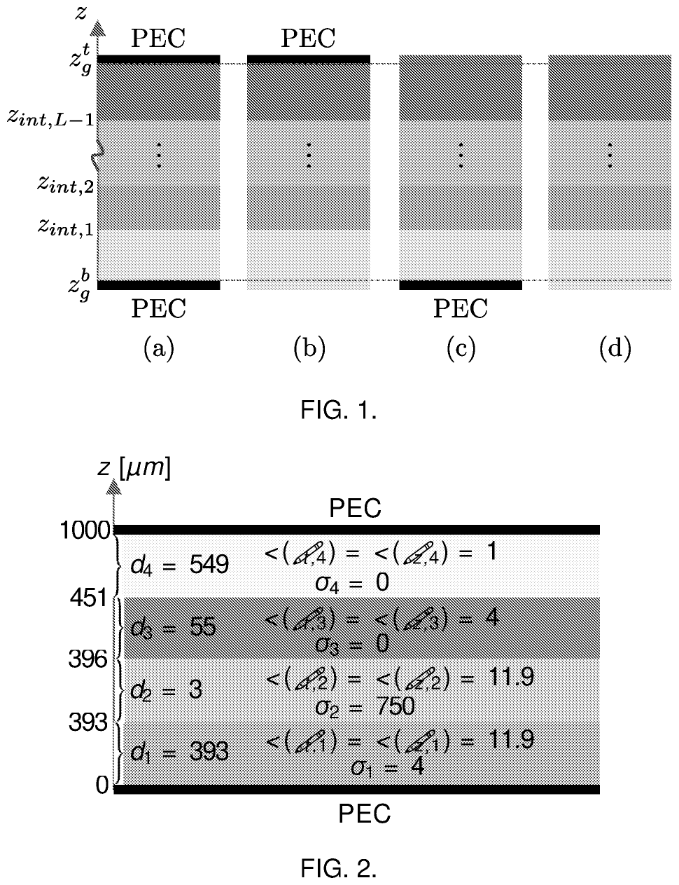

Under the assumption that no magnetic currents are present, it is considered that a electric current source and one or multiple objects are situated in a L-layer planar layered medium. The multilayered medium can be fully shielded by perfect electric conductor (PEC) plates, partially open, or fully open as shown in FIG. 1. In each layer, the laterally infinite medium is assumed to be uniaxially anisotropic and homogeneous. Specifically, each layer is characterized by the constant, and possibly complex-valued, relative permittivity dyadic ε̅=Īₜεₜ+\hat{z}\hat{z}ε_{z}, relative permeability dyadic μ̅=Īₜμₜ+\hat{z}\hat{z}μ_{z}, and electric and magnetic anisotropy ratio v^{e}=εₜ/ε_{z} and v^{h}=μₜ/μ_{z}, where the subscripts t and z mean the parameter in the transverse plane and z direction, respectively.

Formulation C of Michalski-Zheng's representation of the electric field in the layered medium, assuming an e^{jωt} time convention, can be stated, as follows:

$$E = - j {ωμ}_{0} 〈 {\overline{K}}^{A} , J 〉 + \frac{1}{j {ωε}_{0}} ∇ 〈 {G}^{Φ} , {∇}^{′} \cdot J 〉 , \qquad ( 70 )$$

where the dyadic vector potential Green's function K̅^{A}=K̅^{A}(ρ, z|z′) and the scalar Green's function G^{Φ}=G^{Φ}(ρ,z|z′) are dependent on the observation elevation z, lateral distance ρ=\sqrt{x²+y²}, and the source elevation z′ in cylindrical coordinates. Assume the source is located at ρ′=0, the goal of SDEAM is to efficiently and accurately compute the requisite Green's functions.

The dyadic K̅^{A} is expressed as

$${\overline{K}}^{A} = [ \begin{matrix}{K}_{xx}^{A} & 0 & {K}_{xz}^{A} \\ 0 & {K}_{yy}^{A} & {K}_{yz}^{A} \\ {K}_{zx}^{A} & {K}_{zy}^{A} & {K}_{zz}^{A}\end{matrix} ] , \qquad ( 71 )$$

and both K̅^{A} and G^{Φ} are 2-D inverse Fourier transforms in the lateral plane of their spectral counterparts \overline{\tilde{K}}^{A}=\overline{\tilde{K}}^{A}(kₓ,k_{y},z|z′) and \tilde{G}^{Φ}=\tilde{G}^{Φ}(kₓ,k_{y},z|z′):

K̅^{A}= [symbol] ⁻¹{\overline{\tilde{K}}^{A}}, G^{Φ}= [symbol] ⁻¹{\tilde{G}^{Φ}}, (72)

where the 2D forward and inverse Fourier transform pair is defined as

$$\begin{matrix}\tilde{f} ( {k}_{x} , {k}_{y} ) = \{ f ( x , y ) \} \\ = {\int }_{- ∞}^{∞} {\int }_{- ∞}^{∞} f ( x , y ) {e}^{j ( {k}_{x} x + {k}_{y} y )} dxdy\end{matrix} , \qquad ( 73 )$$

$$\begin{matrix}f ( x , y ) = {- 1}^{} \{ \tilde{f} ( {k}_{x} , {k}_{y} ) \} \\ = {\int }_{- ∞}^{∞} {\int }_{- ∞}^{∞} \tilde{f} ( {k}_{x} , {k}_{y} ) {e}^{- j ( {k}_{x} x + {k}_{y} y )} {dk}_{x} {dk}_{y}\end{matrix} . \qquad ( 74 )$$

By formulating the equivalent transmission line for the layered medium, the spectral domain Green's functions are given in terms of TLGFs Vᵢ^{p}, Vᵥ^{p}, Iᵢ^{p}, and Iᵥ^{p} as:

$${\tilde{K}}_{xx}^{A} = {\tilde{K}}_{yy}^{A} = \frac{1}{j ω {μ}_{0}} {V}_{i}^{h} , \qquad ( 75 )$$

$${\tilde{K}}_{xz}^{A} = \frac{{μ}_{t}^{′} {k}_{x}}{{jk}_{ρ}^{2}} ( {V}_{v}^{h} - {V}_{v}^{e} ) , \qquad ( 76 )$$

$${\tilde{K}}_{yz}^{A} = \frac{{μ}_{t}^{′} {k}_{y}}{{jk}_{ρ}^{2}} ( {V}_{v}^{h} - {V}_{v}^{e} ) , \qquad ( 77 )$$

$${\tilde{K}}_{zz}^{A} = \frac{1}{j ω {ε}_{0}} [ ( \frac{{μ}_{t}}{{ε}_{z}^{′}} + \frac{{v}^{e} {μ}_{t}^{′}}{{ε}_{t}^{′}} - \frac{{μ}_{t}^{′} {k}_{t}^{2}}{{ε}_{t} {k}_{ρ}^{2}} ) {I}_{v}^{e} + \frac{{k}_{0}^{2} {μ}_{t} {μ}_{t}^{′}}{{k}_{ρ}^{2}} {I}_{v}^{h} ] , \qquad ( 78 )$$

$${\tilde{G}}^{Φ} = \frac{j ω {ε}_{0}}{{k}_{ρ}^{2}} ( {V}_{i}^{e} - {V}_{i}^{h} ) . \qquad ( 79 )$$

Above, p=e in the transverse magnetic case and p=h in the transverse electric case, k_{ρ}²=kₓ²+k_{y}², kₜ²=k₀²μₜεₜ, k₀²=ω²μ₀ε₀ and ε′ and μ′ represent physical quantities associated with the layer containing the source elevation z′. Based on the properties of the 2D inverse Fourier transform and Bessel functions Jₙ, the inverse Fourier transform of the spectral domain Green's functions can be written as

$${K}_{xx}^{A} = {S}_{0} [ {\tilde{K}}_{xx}^{A} ] , \qquad ( 80 )$$

$${K}_{xz}^{A} = - cos α {S}_{1} [ \frac{{μ}_{t}^{′}}{{k}_{ρ}^{2}} ( {V}_{v}^{h} - {V}_{v}^{e} ) ] , cos α = x / ρ , \qquad ( 81 )$$

$${K}_{yz}^{A} = - sin α {S}_{1} [ \frac{{μ}_{t}^{′}}{{k}_{ρ}^{2}} ( {V}_{v}^{h} - {V}_{v}^{e} ) ] , sin α = y / ρ , \qquad ( 82 )$$

$${K}_{zz}^{A} = {S}_{0} [ {\tilde{K}}_{zz}^{A} ] , \qquad ( 83 )$$

$${G}^{Φ} = {S}_{0} [ {\tilde{G}}^{Φ} ] , \qquad ( 84 )$$

where the Sommerfeld integrals (SIs) Sₙ are defined as

$${S}_{n} [ \tilde{g} ( {k}_{ρ} ) ] = \frac{1}{2 π} {\int }_{0}^{∞} \tilde{g} ( {k}_{ρ} ) {J}_{n} ( {k}_{ρ} ρ ) {k}_{ρ}^{n + 1} {dk}_{ρ} . \qquad ( 85 )$$

In (75)-(79), formulas for \tilde{K}_{zx}^{A} and \tilde{K}_{zy}^{A} are not listed because their spatial domain counterparts can be obtained using the relations

$${k}_{zx}^{A} ( ρ , {z}^{′} \vert z ) = - \frac{{μ}_{t}}{{μ}_{t}^{′}} {K}_{xz}^{A} ( ρ , z \vert {z}^{′} ) , \qquad ( 86 )$$

$${K}_{zy}^{A} ( ρ , {z}^{′} \vert z ) = - \frac{{μ}_{t}}{{μ}_{t}^{′}} {K}_{yz}^{A} ( ρ , z \vert {z}^{′} ) . \qquad ( 87 )$$

The TLGFs in (75)-(79) are governed by ordinary differential equations (ODEs):

$$\frac{{dV}_{i}^{p}}{dz} = - {jk}_{z}^{p} {Z}^{p} {I}_{i}^{p} \qquad ( 88 )$$

$$\frac{{dI}_{i}^{p}}{dz} = - {jk}_{z}^{p} {Y}^{p} {V}_{i}^{p} + δ ( z - {z}^{′} ) \qquad ( 89 )$$

$$\frac{{dV}_{v}^{p}}{dz} = - {jk}_{z}^{p} {Z}^{p} {I}_{v}^{p} + δ ( z - {z}^{′} ) \qquad ( 90 )$$

$$\frac{{dI}_{v}^{p}}{dz} = - {jk}_{z}^{p} {Y}^{p} {V}_{v}^{p} . \qquad ( 91 )$$

The propagation wavenumbers k_{z}^{p}, characteristic impedances Z^{p}, and admittances Y^{p} are defined as

$${k}_{z}^{p} = \sqrt{{k}_{t}^{2} - {v}^{p} {k}_{ρ}^{2}} \qquad ( 92 )$$

$${Z}^{e} = \frac{1}{{Y}^{e}} = \frac{{k}_{z}^{e}}{ω {ε}_{0} {ε}_{t}} \qquad ( 93 )$$

$${Z}^{h} = \frac{1}{{Y}^{h}} = \frac{ω {μ}_{0} {μ}_{t}}{{k}_{z}^{h}} . \qquad ( 94 )$$

The analytical solutions of TLGFs are formulated by Michalski and Mosig paper titled “Multilayered Media Green's Functions in Integral Equation Formulations” published by IEEE Transactions on Antennas and propagation in 1997. Subsequently, one can construct the spectral domain Green's functions, evaluate the SIs (80)-(84), and apply (86) and (87), to obtain the mixed-potential Green's functions. However, the SIs in (80)-(84) are computationally heavy due to the oscillatory, singular and divergent behaviours of the integrands, especially in their tails. The SDEAM is introduced to circumvent this cost.

The goal is to generate, for a given z′ and ρ, the Green's functions K̅^{A} and G^{Φ} in the solution domain z∈D=[z^{b},z^{t}], where z^{b} and z^{t} denote the bottom and top boundaries of the solution domain.

The SDEAM framework is a two-step approach for computing spatial Green's functions by first solving for the spectral Green's function in pole-residue form and then evaluating the associated Sommerfeld integrals analytically.

By taking the derivative of (88) and (91) and substituting (89) and (90), the voltage and current can be decoupled, the resultant 2nd order ordinary differential equations governing Vᵢ^{p} and Iᵥ^{p} are

$$\frac{{d}^{2} {V}_{i}^{p}}{{dz}^{2}} + {( {k}_{z}^{p} )}^{2} {Z}^{p} {Y}^{p} {V}_{i}^{p} = - {jk}_{z}^{p} {Z}^{p} δ ( z - {z}^{′} ) , \qquad ( 95 )$$

$$\frac{{d}^{2} {I}_{v}^{p}}{{dz}^{2}} + {( {k}_{z}^{p} )}^{2} {Z}^{p} {Y}^{p} {I}_{v}^{p} = - {jk}_{z}^{p} {Y}^{p} δ ( z - {z}^{′} ) . \qquad ( 96 )$$

At the [symbol] th dielectric interface located at [symbol] , the boundary conditions for the TLGEs enforce continuity of the voltage and current:

$${V}_{s}^{p} {\vert}_{{z}_{int , ℓ}^{-}} = {V}_{s}^{p} {\vert}_{{z}_{int , ℓ}^{+}} \qquad ( 97 )$$

$${I}_{s}^{p} {\vert}_{{z}_{int , ℓ}^{-}} = {I}_{s}^{p} {\vert}_{{z}_{int , ℓ}^{+}} , \qquad ( 98 )$$

where s=i or v represents the type of source.

The medium boundary is denoted as z_{bdry}. If the medium is terminated by a PEC plate, the boundary condition at z_{bdry} are

Vₛ^{p}|_{z}_{_{bdry}}=0, (99)

and

$$\frac{{dI}_{s}^{p}}{dz} {\vert}_{{z}_{bdry}} = 0. \qquad ( 100 )$$

If the medium is not terminated and the radiation boundary condition is enforced at z_{bdry}, the boundary condition at z_{bdry} are

$$\frac{{dV}_{s}^{p}}{dz} {\vert}_{{z}_{bdry}} \pm j \sqrt{{k}_{0}^{2} - {k}_{ρ}^{2}} {V}_{s}^{p} {\vert}_{{z}_{bdry}} = 0 , \qquad ( 101 )$$

$$and$$

$$\frac{{dI}_{s}^{p}}{dz} {\vert}_{{z}_{bdry}} \pm j \sqrt{{k}_{0}^{2} - {k}_{ρ}^{2}} {I}_{s}^{p} {\vert}_{{z}_{bdry}} = 0 , \qquad ( 102 )$$

In (101) and (102), the plus sign is taken when the medium is open on top, and minus sign is taken when the medium is open on bottom.

The full BVP of a TLGF is formulated by picking the corresponding ODE and BCs from (95)-(102). The SDEAM requires the solutions of these BVPs in pole-residue form where the dependence on k_{ρ}² in the system of linear algebraic equations (SLAE) is linear; it is this form that permits analytic evaluation of the required SIs. Unfortunately, when formulating the BVP for Vᵢ^{e}, the BC (98) introduces a non-linear dependence on k_{ρ}². A similar issue arises when formulating the BVP for Iᵥ^{h} due to (97). To fix this, one can choose to define the normalized voltage \hat{V}ᵢ^{e} as

$${\hat{V}}_{i}^{e} = \frac{ω {ε}_{0} {ε}_{t}}{{k}_{t}^{2} - {μ}^{e} {k}_{ρ}^{2}} {V}_{i}^{e} , \qquad ( 103 )$$

and the normalized current as

$${\hat{I}}_{v}^{h} = \frac{ω {μ}_{0} {μ}_{t}}{{k}_{t}^{2} - {μ}^{h} {k}_{ρ}^{2}} {I}_{v}^{h} . \qquad ( 104 )$$

Rewriting (97) and (98) in terms of these normalized quantities, and using (88) or (91) to derive appropriate boundary conditions, ensures that the formulated BVPs for \hat{V}ᵢ^{e} and Îᵥ^{h} permit pole-residue forms with the desired dependence on k_{ρ}.

When dealing with the partially or fully open medium, the square root in the radiation boundary condition is approximated as

$$\frac{1}{\sqrt{{k}_{0}^{2} - {k}_{ρ}^{2}}} ≅ {\sum }_{p = 1}^{P - 1} \frac{{C}_{p}}{{k}_{ρ}^{2} - {α}_{p}} + {C}_{0} \qquad ( 105 )$$

where Cₚ are known coefficients, αₚ are known poles generated by the VECTFIT algorithm described by Gustavsen and Semlyen in paper titled “Rational Approximation of Frequency Domain Responses by vector fitting” published by IEEE Transactions on Power Delivery. Auxiliary variables

$${{E}_{p} = \frac{{C}_{p}}{{k}_{ρ}^{2} - {α}_{p}} \frac{dX}{d 𝓏} \vert}_{{𝓏}_{N}} , p = 1 , , 2 , … , P \qquad ( 106 )$$

are introduced to the corresponding unknown vector of SLAE associated with TLGF X. This rational function approximation and the introduction of auxiliary variables combine the ODE and RBC at the open medium boundary truncation while still enable pole residue representations of X.

One can cast the BVP of a TLGF into SLAEs numerically. Such numerical methods include finite difference method, finite element method and its variant such as discontinuous Galerkin method. The resultant generic form of the SLAE is

(A^{X}+k_{ρ}²B^{X})X=b^{X}, (107)

where X may represent Vᵢ^{h}, Iᵥ^{e}, Îᵥ^{h}, or \hat{V}ᵢ^{e}, b^{X} is the known excitation vector. The dimensions of matrices A^{X} and B^{X} may differ when X represent different TLGF, depending on the continuity behaviour of X at dielectric interfaces.

Once the SLAE (107) is formulated, one can perform matrix decomposition

E^{X}D^{X}(E^{X})⁻¹=(B^{X})⁻¹A^{X}, (108)

deine matrix T^{X}=(B^{X}E^{X})⁻¹, and formulate the pole-residue form for all unknowns X

X=E^{X}(D^{X}+k_{ρ}²I)⁻¹T^{X}b, (109)

equivalently, the nth unknown Xₙ=X(k_{ρ},zₙ;z′) has pole-residue form

$${X}_{n} = {\sum }_{v ∈ S} {b}_{v}^{X} {\sum }_{m = 1}^{M} \frac{{E}_{n m}^{X} {T}_{mv}^{X}}{{D}_{m m}^{X} + {k}_{ρ}^{2}} \qquad ( 110 )$$

where M is the dimension of the SLAE for X, or equivalently the number of entries in X. The set S contains the non-zero entries of the RHS vector.

When X=Vᵢ^{h} or Iᵥ^{e}, the pole residue forms of them are

$${V}_{i , n}^{h} = {\sum }_{s ∈ S} {b}_{s}^{{V}_{i}^{h}} {\sum }_{m = 1}^{{N}_{c}} \frac{{E}_{n m}^{{V}_{i}^{h}} {T}_{m s}^{{V}_{i}^{h}}}{{D}_{m m}^{{V}_{i}^{h}} + {k}_{ρ}^{2}} , \qquad ( 111 )$$

$${I}_{v , n}^{e} = {\sum }_{s ∈ S} {b}_{s}^{{I}_{v}^{e}} {\sum }_{m = 1}^{{N}_{c}} \frac{{E}_{n m}^{{I}_{v}^{e}} {T}_{m s}^{{I}_{v}^{e}}}{{D}_{m m}^{{I}_{v}^{e}} + {k}_{ρ}^{2}} , \qquad ( 112 )$$

where N_{c} is the size of the SLAE of Vᵢ^{h} or equivalently Iᵥ^{e} on the same set of discretization nodes.

When X=\hat{V}ᵢ^{e} or X=Îᵥ^{h}, one need to first write \hat{V}ᵢ^{e,n} and Îᵥ^{h,n} in the form of (110), then obtain the pole-residue form of Vᵢ^{e} and Iᵥ^{h} based on the relationships (103) (104) by denormalization. The results are

$${V}_{i , n}^{e} = \frac{{k}_{t , n}^{2}}{{ωε}_{0} {ε}_{t , n}} {\sum }_{s ∈ S} {b}_{s}^{{\hat{V}}_{i}^{e}} {\sum }_{m = 1}^{{N}_{d}} \frac{{E}_{n m}^{{\hat{V}}_{i}^{e}} {T}_{m s}^{{\hat{V}}_{i}^{e}}}{{D}_{m m}^{{\hat{V}}_{i}^{e}} + {k}_{ρ}^{2}} - \frac{{ν}_{n}^{e}}{{ωε}_{0} {ε}_{t , n}} {\sum }_{s ∈ S} {b}_{s}^{{\hat{V}}_{i}^{e}} {\sum }_{m = 1}^{{N}_{d}} \frac{{E}_{n m}^{{\hat{V}}_{i}^{e}} {T}_{m s}^{{\hat{V}}_{i}^{e}} {k}_{ρ}^{2}}{{D}_{m m}^{{\hat{V}}_{i}^{e}} + {k}_{ρ}^{2}} , \qquad ( 113 )$$

$${I}_{v , n}^{h} = \frac{{k}_{t , n}^{2}}{{ωμ}_{0} {μ}_{t , n}} {\sum }_{s ∈ S} {b}_{s}^{{\hat{I}}_{v}^{h}} {\sum }_{m = 1}^{{N}_{d}} \frac{{E}_{n m}^{{\hat{I}}_{v}^{h}} {T}_{m s}^{{\hat{I}}_{v}^{h}}}{{D}_{m m}^{{\hat{I}}_{v}^{h}} + {k}_{ρ}^{2}} - \frac{{ν}_{n}^{h}}{{ωμ}_{0} {μ}_{t , n}} {\sum }_{s ∈ S} {b}_{s}^{{\hat{I}}_{v}^{h}} {\sum }_{m = 1}^{{N}_{d}} \frac{{E}_{n m}^{{\hat{I}}_{v}^{h}} {T}_{m s}^{{\hat{I}}_{v}^{h}} {k}_{ρ}^{2}}{{D}_{m m}^{{\hat{I}}_{v}^{h}} + {k}_{ρ}^{2}} , \qquad ( 114 )$$

where N_{d} is the size of the SLAE of \hat{V}ᵢ^{e} or equivalently Îᵥ^{h} on the same set of discretization nodes.

The pole residue representations of TLGFs for Iᵢ^{h}, Vᵥ^{e}, Iᵢ^{e}, and Vᵥ^{h} are not solved directly from SLAEs. Instead, they are obtained by taking the derivative of the corresponding TLGFs that are numerically solved in SLAEs according to (88) and (91).

If finite element method or its variant like discontinuous Galerkin method is used to formulate SLAEs of TLGFs, the pole residue results for Iᵢ^{h}, Vᵥ^{e}, Iᵢ^{e}, and Vᵥ^{h} are

$${I}_{i , n}^{h} = \frac{j}{{ωμ}_{0} {μ}_{t}^{{k}_{n}}} {\sum }_{q = 1}^{{N}_{p}^{{k}_{n}}} {( {l}_{q}^{{k}_{n}} )}^{′} {\vert}_{{𝓏}_{n}} {\sum }_{s ∈ S} {b}_{s}^{{V}_{i}^{h}} {\sum }_{m = 1}^{{N}_{c}} \frac{{E}_{{n}_{q}^{{k}_{n}} m}^{{V}_{i}^{h}} {T}_{m s}^{{V}_{i}^{h}}}{{D}_{m m}^{{V}_{i}^{h}} + {k}_{ρ}^{2}} \qquad ( 115 )$$

$${I}_{i , n}^{e} = j {\sum }_{q = 1}^{{N}_{p}^{{k}_{n}}} {( {l}_{q}^{{k}_{n}} )}^{′} {\vert}_{{𝓏}_{n}} {\sum }_{s ∈ S} {b}_{s}^{{\hat{V}}_{i}^{e}} {\sum }_{m = 1}^{{N}_{d}} \frac{{E}_{{n}_{q}^{{k}_{n}} m}^{{\hat{V}}_{i}^{e}} {T}_{m s}^{{\hat{V}}_{i}^{e}}}{{D}_{m m}^{{\hat{V}}_{i}^{h}} + {k}_{ρ}^{2}} \qquad ( 116 )$$

$${V}_{v , n}^{e} = \frac{j}{{ωε}_{0} {ε}_{t}^{{k}_{n}}} {\sum }_{q = 1}^{{N}_{p}^{{k}_{n}}} {( {l}_{q}^{{k}_{n}} )}^{′} {\vert}_{{𝓏}_{n}} {\sum }_{s ∈ S} {b}_{s}^{{I}_{v}^{e}} {\sum }_{m = 1}^{{N}_{c}} \frac{{E}_{{n}_{q}^{{k}_{n}} m}^{{I}_{v}^{e}} {T}_{m s}^{{I}_{v}^{e}}}{{D}_{m m}^{{I}_{v}^{e}} + {k}_{ρ}^{2}} \qquad ( 117 )$$

$${V}_{v , n}^{h} = j {\sum }_{q = 1}^{{N}_{p}^{{k}_{n}}} {( {l}_{q}^{{k}_{n}} )}^{′} {\vert}_{{𝓏}_{n}} {\sum }_{s ∈ S} {b}_{s}^{{\hat{I}}_{v}^{h}} {\sum }_{m = 1}^{{N}_{d}} \frac{{E}_{{n}_{q}^{{k}_{n}} m}^{{\hat{I}}_{v}^{h}} {T}_{m s}^{{\hat{I}}_{v}^{h}}}{{D}_{m m}^{{\hat{I}}_{v}^{h}} + {k}_{ρ}^{2}} \qquad ( 118 )$$

where kₙ being the index of the element that contains the nth discretization node, and l_{q} being the basis function.
If finite difference method is used to formulate SLAEs of TLGFs, the derivative is taken by central, forward, or backward difference rule.

The spectral domain Green's functions in pole-residue forms are obtained from the pole-residue forms of the TLGFs according to (75)-(79). The evaluation of the Sommerfeld integrals (80)-(84) can then be performed analytically by contour deformation, where one can numerically demonstrate that the residues are the only contributor to the SI value. The spatial domain Green's functions K̅^{A} and G^{Φ} at the nth global discretization node, i.e., K_{xx,n}^{A}=Kₓₓ^{A}(ρ,zₙ|z′), K_{xz,n}^{A}=K_{xz}^{A}(ρ,zₙ|z′), K_{yz,n}^{A}=K_{yz}^{A}(ρ,zₙ|z′), K_{zz,n}^{A}=K_{zz}^{A}(ρ,zₙ|z′), Gₙ^{Φ}=G^{Φ}(ρ,zₙ|z′) are given as

$${K}_{xx , n}^{A} = \frac{1}{2 π j {ωμ}_{0}} {\sum }_{s ∈ S} {b}_{s}^{{V}_{i}^{h}} {\sum }_{m = 1}^{{N}_{c}} {E}_{n m}^{{V}_{i}^{h}} {T}_{m s}^{{V}_{i}^{h}} {η}_{1} ( {D}_{m m ,}^{{V}_{i}^{h}} ρ ) \qquad ( 119 )$$

$$\{ \begin{matrix}{K}_{xz , n}^{A} \\ {K}_{yz , n}^{A}\end{matrix} \} = \{ \begin{matrix}cos α \\ sin α\end{matrix} \} ( \frac{j {μ}_{t}^{′}}{2 {πωε}_{0} {ε}_{t}^{{k}_{n}}} {\sum }_{q = 1}^{{N}_{p}^{{k}_{n}}} {( {l}_{q}^{{k}_{n}} )}^{′} {\vert}_{{𝓏}_{n}} {\sum }_{s ∈ S} {b}_{s}^{{I}_{v}^{e}} {\sum }_{m = 1}^{{N}_{c}} {E}_{{n}_{q}^{{k}_{n}} m}^{{I}_{v}^{e}} {T}_{m s}^{{I}_{v}^{e}} {η}_{2} ( {D}_{m m}^{{I}_{v}^{e}} , ρ ) - \frac{j {μ}_{t}^{′}}{2 π} {\sum }_{q = 1}^{{N}^{{k}_{n}}} {( {l}_{q}^{{k}_{n}} )}^{′} {\vert}_{{𝓏}_{n}} {\sum }_{s ∈ S} {b}_{s}^{{\hat{I}}_{v}^{h}} {\sum }_{m = 1}^{{N}_{d}} {E}_{{n}_{q}^{{k}_{n}} m}^{{\hat{I}}_{v}^{h}} {T}_{m s}^{{\hat{I}}_{v}^{h}} {η}_{2} ( {D}_{m m}^{{\hat{I}}_{v}^{h}} , ρ ) ) \qquad ( 120 )$$

$${K}_{zz , n}^{A} = \frac{1}{2 π j ω {μ}_{0}} [ ( \frac{{μ}_{t}^{{k}_{n}}}{{ε}_{z}^{′}} + {v}_{e}^{{k}_{n}} \frac{{μ}_{t}^{′}}{{ε}_{t}^{{k}_{n}}} ) {\sum }_{s ∈ S} {b}_{s}^{{I}_{v}^{e}} {\sum }_{m = 1}^{{N}_{c}} {E}_{n m}^{{I}_{v}^{e}} {T}_{m s}^{{I}_{v}^{e}} {η}_{1} ( {D}_{m m}^{{I}_{v}^{e}} , ρ ) - \frac{{( {k}_{t}^{2} )}^{{k}_{n}} {μ}_{t}^{′}}{{ε}_{t}^{{k}_{n}}} {\sum }_{s ∈ S} {b}_{s}^{{I}_{v}^{e}} {\sum }_{m = 1}^{{N}_{c}} {E}_{n m}^{{I}_{v}^{e}} {T}_{m s}^{{I}_{v}^{e}} {η}_{3} ( {D}_{m m}^{{I}_{v}^{e}} , ρ ) - {ωε}_{0} {{μ}_{t}^{′} ( {v}^{h} )}^{{k}_{n}} {\sum }_{s ∈ S} {b}_{s}^{{\hat{I}}_{v}^{h}} {\sum }_{m = 1}^{{N}_{d}} {E}_{n m}^{{\hat{I}}_{v}^{h}} {T}_{m s}^{{\hat{I}}_{v}^{h}} {η}_{1} ( {D}_{m m}^{{\hat{I}}_{v}^{h}} , ρ ) ] \qquad ( 121 )$$

$${G}_{n}^{Φ} = \frac{j}{2 π} [ ( \frac{{k}_{t , n}^{2}}{{ε}_{t , n}} ) {\sum }_{s ∈ S} {b}_{s}^{{\hat{V}}_{i}^{e}} {\sum }_{m = 1}^{{N}_{c}} {E}_{n m}^{{\hat{V}}_{i}^{e}} {T}_{m s}^{{\hat{V}}_{i}^{e}} {η}_{3} ( {D}_{m m}^{{\hat{V}}_{i}^{e}} , ρ ) - \frac{{ν}_{e , n}}{{ε}_{t , n}} {\sum }_{s ∈ S} {b}_{s}^{{\hat{V}}_{i}^{e}} {\sum }_{m = 1}^{{N}_{c}} {E}_{n m}^{{\hat{V}}_{i}^{e}} {T}_{m s}^{{\hat{V}}_{i}^{e}} {η}_{1} ( {D}_{m m ,}^{{\hat{V}}_{i}^{e}} ρ ) - {ωε}_{0} {\sum }_{s ∈ S} {b}_{s}^{{V}_{i}^{h}} {\sum }_{m = 1}^{{N}_{d}} {E}_{n m}^{{V}_{i}^{h}} {T}_{m s}^{{V}_{i}^{h}} {η}_{3} ( {D}_{m m}^{{V}_{i}^{h}} , ρ ) ] \qquad ( 122 )$$

wherein the functions η₁, η₂, and η₃ are

$${η}_{1} ( {D}_{m m ,} ρ ) = - \frac{π j}{2} {H}_{0}^{( 2 )} ( - j \sqrt{{D}_{m m}} ρ ) \qquad ( 123 )$$

$${η}_{2} ( {D}_{m m ,} ρ ) = - \frac{π}{2 \sqrt{{D}_{m m}}} {H}_{1}^{( 2 )} ( - j \sqrt{{D}_{m m}} ρ ) \qquad ( 124 )$$

$${η}_{3} ( {D}_{m m ,} ρ ) = - \frac{π j}{2 {D}_{m m}} {H}_{0}^{( 2 )} ( - j \sqrt{{D}_{m m}} ρ ) . \qquad ( 125 )$$

The other off-diagonal entries of K̅^{A} in its third row, namely K_{zx}^{A} and K_{zy}^{A} can be obtained from the reciprocity relations (86) and (87) rather than calculated from the TLGFs.

Mixed potential Green's functions K̅^{F} and G^{Ψ} in mixed representation of H is related to TLGFs according to (75) to (79) and replacement of symbols A→F, Φ→Ψ, ε→μ, μ→ε, V→I, I→V, v→i, i→v, e→h, h→e and also can be solved by SDEAM.

For a fully shielded structure shown as in FIG. 2, a high-order DGM based SDEAM is used to generate the mixed potential Green's functions. Results are compared with Green's function data generated by DCIM with 5 images, where the DCIM level is adaptively determined. The frequency is chosen at 30 GHz, making the free space wavelength approximately 10 mm. The smallest wavelength occurs in the thin, highly lossy layer at around 658 μm. The point source is located in the third layer at z′=420 μm. The mesh for SDEAM is generated by Gmsh such that the number of elements is fixed at 20 for all layers except for the third layer in which the source resides. In the source layer, elements sizes are fixed at 1 μm, resulting 55 elements in that layer. All elements use a basis expansion order set to p=4, resulting in 461 unique nodes over z. Note that when presenting results as a function of z, not all z samples are shown and the density of z samples varies within the layers.

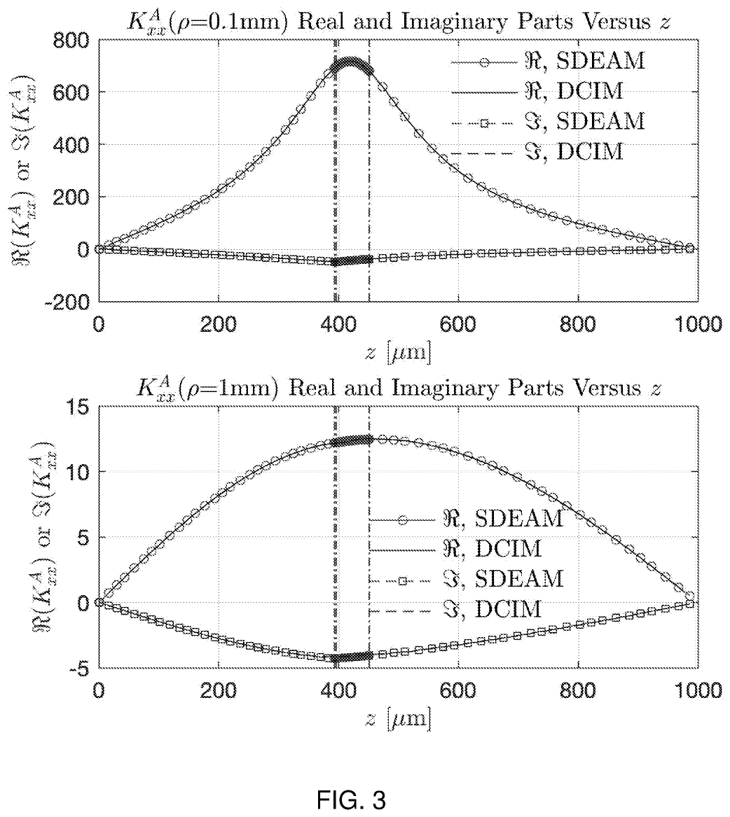

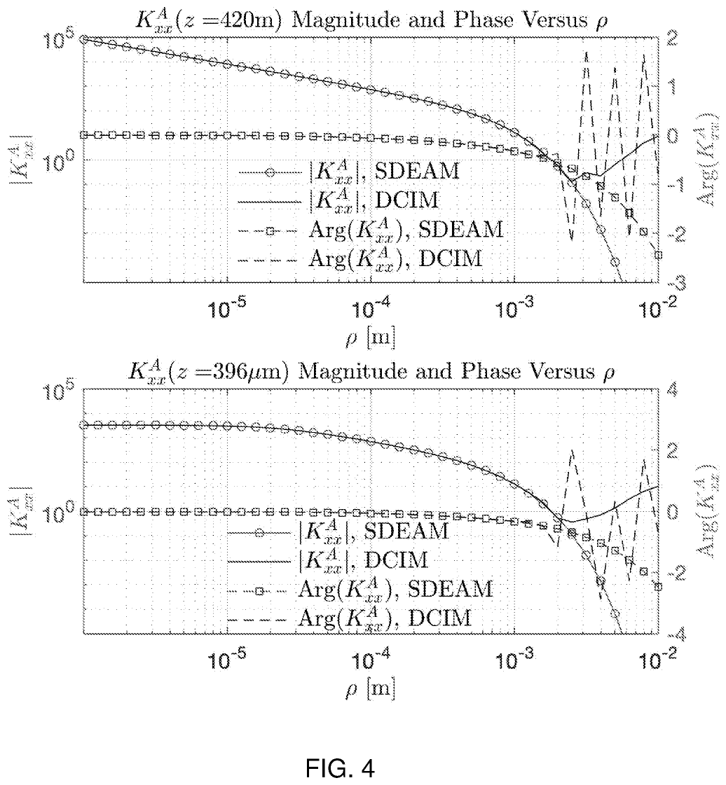

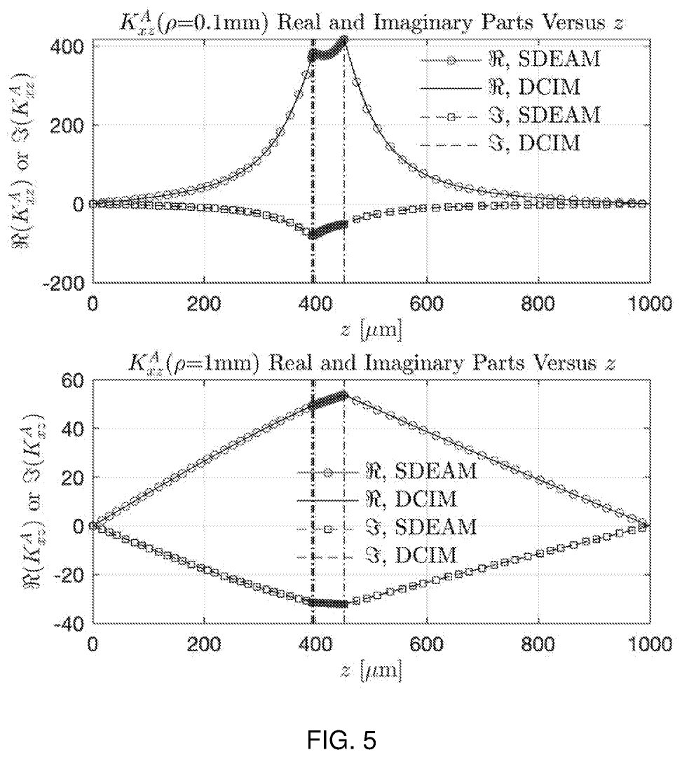

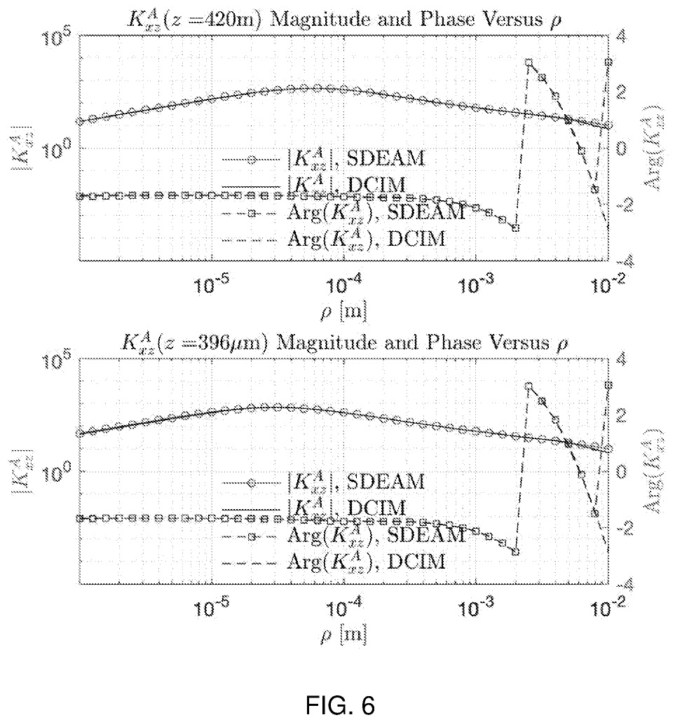

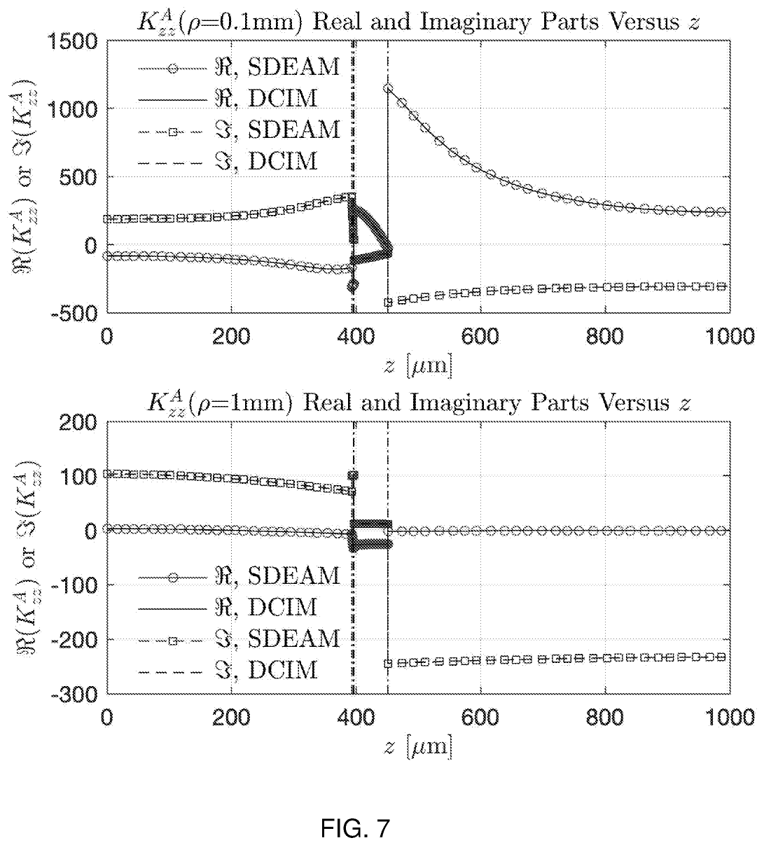

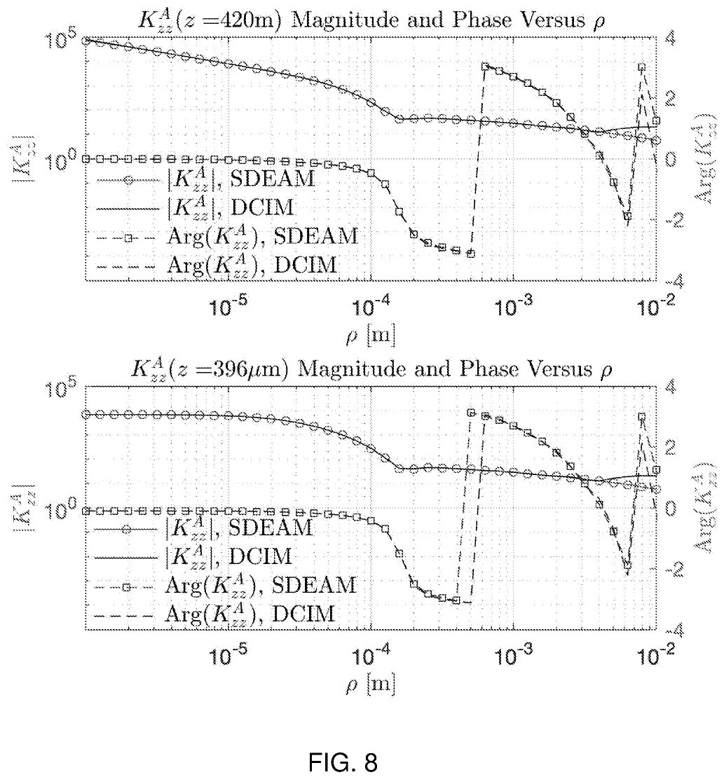

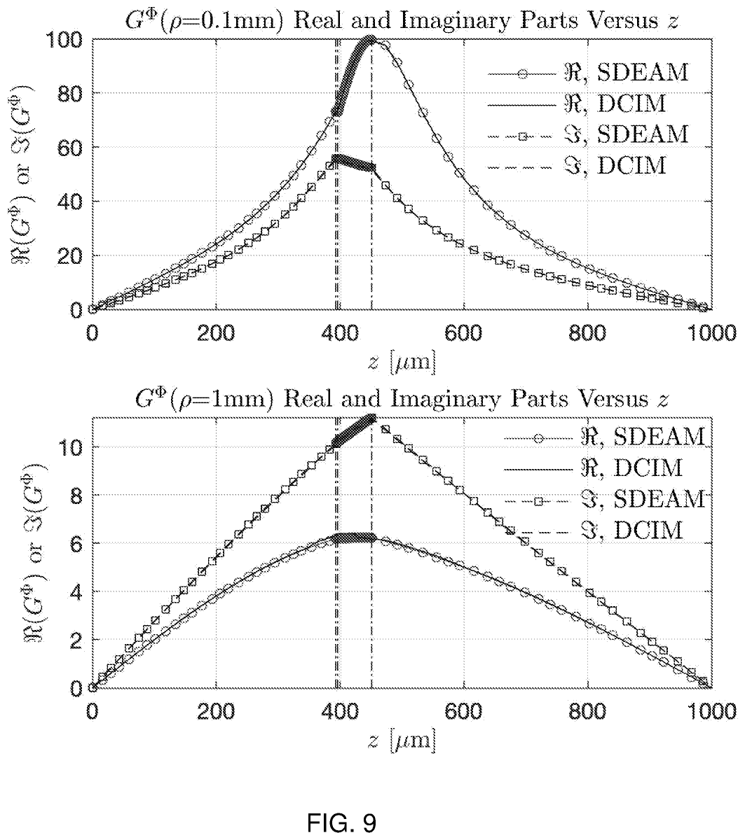

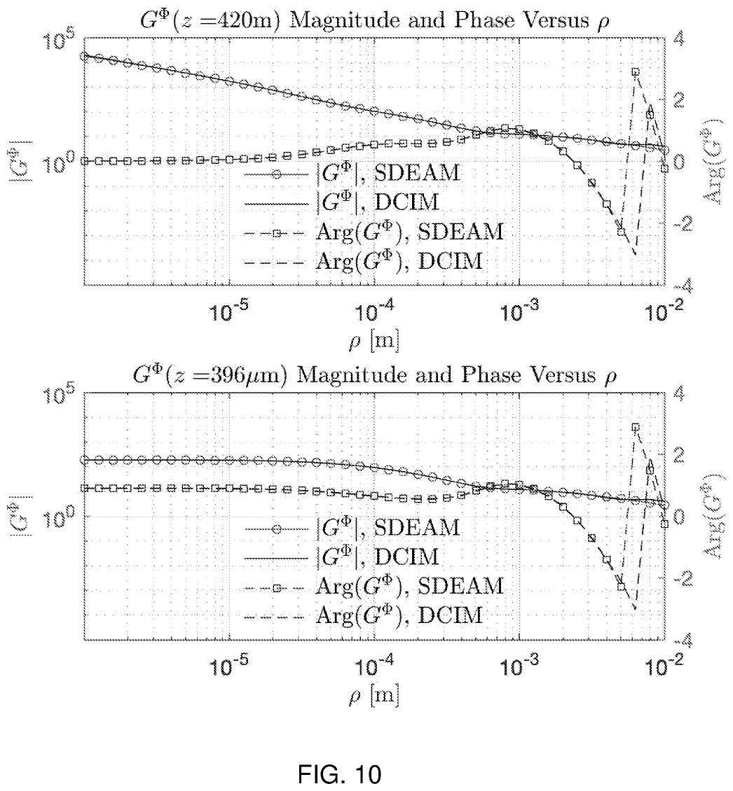

FIG. 3 to FIG. 10 compare the the magnitude, phase, real part, and imaginary part of Green's function components computed using SDEAM and DCIM; components not shown are either a scaled version or the reciprocal of a presented component. In the figures, components are scaled for different values of ρ or z (as indicated on the vertical axis label) to make the figures more discernible. In the fixed-ρ figures, one can observe good agreement of the results between the SDEAM- and DCIM-generated Green's function data when ρ is fixed in the near-field region. For the fixed-z figures, the Green's function data matches up to ρ=1 mm, which is about one free space wavelength. DCIM breaks down after that lateral distance, behaviour that is well documented. SDEAM does not exhibit such breakdown due to its reliable spectral domain solution and the fact that the Hankel functions in the spatial equations accurately accounts for the physical cylindrical wave behaviour. The robustness of the SDEAM is its primary advantage over DCIM.

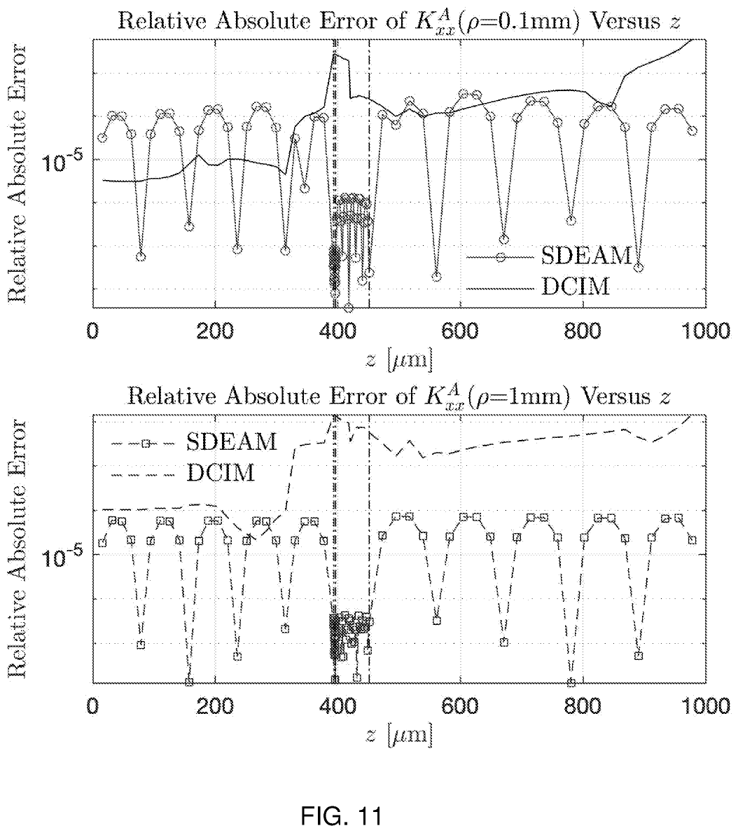

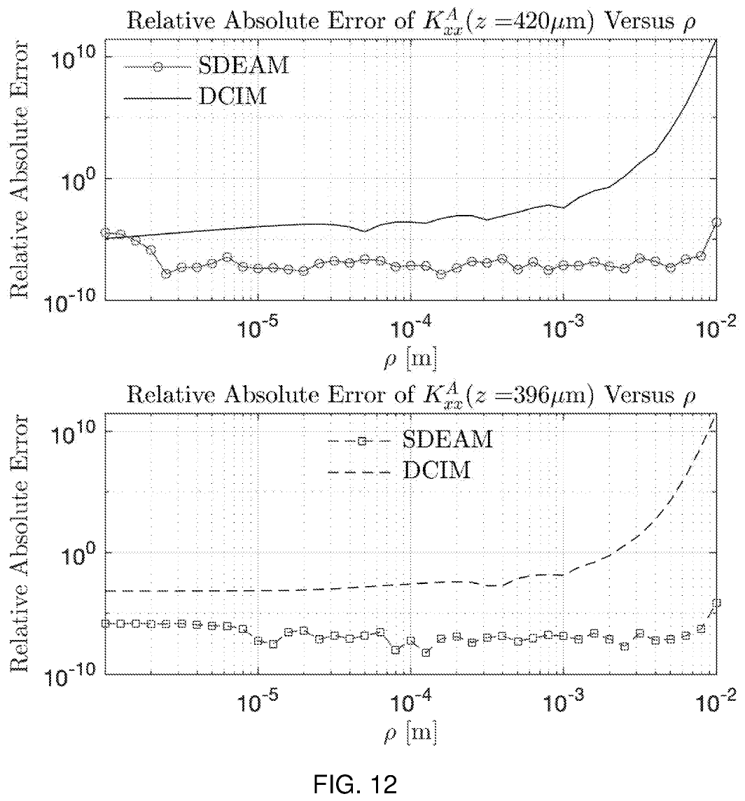

To quantify the performance of SDEAM and DCIM, the relative error plots for Kₓₓ^{A} in FIG. 11 and FIG. 12. While this kernel is the simplest for SDEAM to compute according to the closed-form expressions, it is sufficiently representative of other kernel component error behaviour. For brevity, error plots for other kernels are not presented. The benchmark data used to calculate the relative error in the kernel as a function of either z or ρ was generated using weighted average (WA) extrapolation method, described by Michalski and Mosig in paper titled “Efficient computation of Sommerfeld integral tails—methods and algorithms” published by IEEE Journal of Electromagnetic Waves and Applications. WA was configured with both the partial extrapolation tolerance and adaptive integration tolerance set to 10⁻¹⁵, with the aim of achieving a reliable benchmark while acknowledging that WA may have difficulties with large ρ values. In the error plots versus z in FIG. 11, both SDEAM and DCIM have similar error levels; FIG. 12 shows that SDEAM retains accuracy as ρ increases, while the DCIM error becomes unbounded for large ρ. Note that though it appears that SDEAM may be starting to lose accuracy at values of ρ near 0.01 m, this increased error is in fact due to the WA benchmark losing accuracy as a result of the extremely small value of the kernel at this distance.

A comparison of the time required to evaluate Kₓₓ^{A} is shown in Table 1. Other kernels have similar behaviours and are not listed for brevity. Based on the experimental settings, SDEAM generates 461 Kₓₓ^{A} samples for a fixed value of ρ. When tabulating the timir we chose ρ=0.1 mm. DCIM and WA were used to generate the same number of Kₓₓ^{A} samples.

TABLE 1
A comparison of the execution time to compute Kₓₓ^{A} using
SDEAM, DCIM, and WA at 461 observation z nodes for z′ = 420 μm.
Execution Time (s)

| Method | 1 ρ sample | 51 ρ samples |
|---|---|---|
| SDEAM | 21.14 | 21.29 |
| DCIM | 43.12 | 2199.12 |
| WA | 3988.48 | 2.03 × 105 |

The execution results for a single ρ sample show that, for the given configurations, SDEAM is the fastest method of all three. DCIM is relatively fast, while WA is intolerably slow, attributed to the small partial extrapolation tolerance and adaptive integration tolerance used while seeking benchmark data. If one instead sets these tolerances to 10⁻⁹, the WA execution time for a single ρ sample is 47 seconds, still the slowest of the three.
While the code was timed for a single ρ sample, it is valuable to extrapolate the expected execution time for, say, 51 ρ samples, also shown in Table 1. The bulk of the single ρ-sample SDEAM time is devoted to generating the DGM matrices (13.87 s); and using them to determine the required SDEAM operators (7.26 s). The costs associated with these computations are O(N_{c}³), that is they depend only on then umber of z-samples. Once the SDEAM operators were computed, it only took 3.15 ms to evaluate the closed form Kₓₓ^{A} formula (159). It follows that the time required to compute 51 ρ-samples is essentially the same as the time required to compute a single sample. In contrast, the execution time of both DCIM and WA scale linearly with the number of ρ samples, which leads to the long execution times present in the table when seeking additional samples. The ability for SDEAM to very efficiently tabulate additional kernel values as a function of ρ is advantageous when constructing a Green's function database for MoM solvers, as the number of ρ samples will have minimal effect on the total execution time.

In terms of memory requirements for a single ρ and 461 z samples, SDEAM used 56 MB to store all matrices, operators, and Kₓₓ^{A} data. The memory requirements for the matrices and operators grows proportionally to the number of z-samples as O(N_{c}²), but do not grow with the number of ρ samples. DCIM and WA used 345 MB and 8 MB respectively. We acknowledge that our in-house implementations have not been optimized for memory use. The number of z samples sought here for a realistic geometry demonstrates that SDEAM has reasonable time and memory requirements. As the number of z-samples grows, SDEAM will pay O(N_{c}³) time increases and O(N_{c}²) memory increases. This, however, is not a problem for practical computations when the number of z samples ranges from tens to several hundreds.

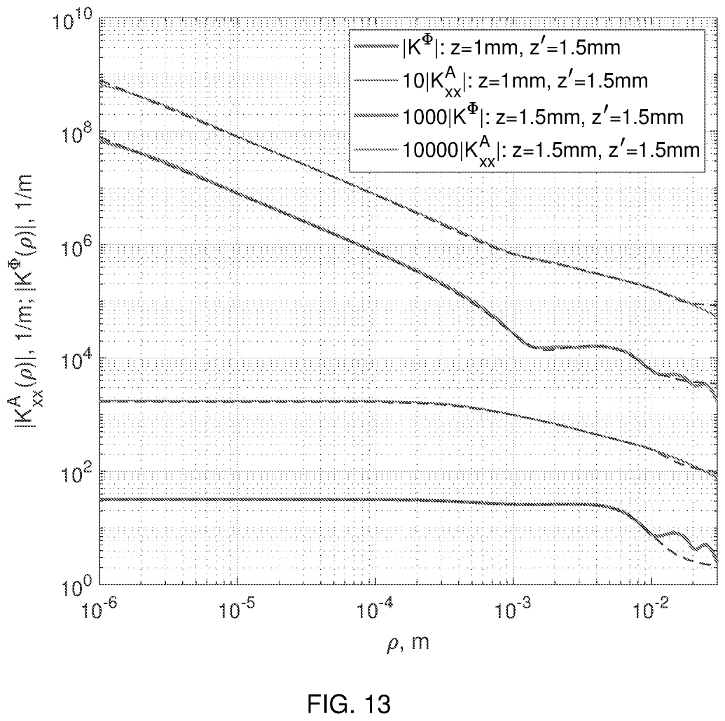

For a two-layer medium partially open on top, a finite difference based SDEAM is applied to compute the mixed potential Green's function components Kₓₓ^{A} and G^{Φ}, the results are compared with DCIM. The bottom layer of thickness 1 mm is filled with dielectric characterized by relative dielectric permittivity εᵣ=11.9, conductivity 0.5 S/m, and relative permeability μᵣ=1. A PEC plate located at z_{g}^{b}=0 shields the medium from the bottom. The dielectric is open in air, i.e., the top layer of the medium extends to z=∞ in air. A 30 GHz x-directed electric dipole source is placed in the air at elevation z′=1.5 mm. The finite difference solution in SDEAM was obtained on N=601 point equidistant grid. The discretization of the domain is truncated at z^{t}=2 mm. The mixed-potential Green's functions kernels Kₓₓ^{A} and K^{Φ} versus the lateral distance ρ at the dielectric interface elevation z=1 mm and at the dipole elevation z′=1.5 mm are shown in FIG. 13. From the results one can see good agreement between SDEAM and DCIM mixed potential Green's functions results until DCIM breaks down in the far field.

In one application, the conductive elements comprise interconnects within a circuit assembly and the multilayered medium comprises stratified layers of the circuit assembly. In this instance, the method includes solving for electric current in the circuit assembly.

In another application, the conductive grounding element comprises a structural metal frame embedded within a concrete foundation structure and the multilayered medium comprises layers of Earth soil. In this instance, the method includes solving for electric current in both the conductive grounding elements and the concrete foundation structure.

In another application, the dielectric elements comprise optical interconnects within an integrated photonics assembly and the multilayered medium comprises stratified layers of the photonics assembly. In this instance, the method includes solving for electric and magnetic currents in the photonics assembly.

In another application, the dielectric elements comprise underground natural resource formations within the layers of soil and the multilayered medium comprises layers of Earth strata. In this instance, the method includes solving for electric and magnetic currents in the natural resource formations.

In another application, the dielectric elements comprise sea ice formations within the ocean ice sheets and the multilayered medium comprises layers of sea ice, water, and snow. In this instance, the method includes solving for electric and magnetic currents in the natural and man-made inegularities present in the layers.

Since various modifications can be made in the invention as herein above described, and many apparently widely different embodiments of same made, it is intended that all matter contained in the accompanying specification shall be interpreted as illustrative only and not in a limiting sense.

What is claimed is:

1. A method of electromagnetic analysis of one or more elements in uniaxially anisotropic multilayered media, the method comprising:
(i) representing one or both of the electric field and the magnetic field in multilayered media due to given electric current J and magnetic current M in the form containing mixed potential contributions [symbol] K̅^{A},J [symbol] , ∇ [symbol] G^{Φ}, ∇′·J [symbol] , [symbol] K̅^{F},M [symbol] , and ∇ [symbol] G^{Ψ}, ∇′·M [symbol] , the electric field being expressed as
$$E = - j ω {μ}_{0} 〈 {\overline{K}}^{A} , J 〉 + \frac{1}{j ω {ε}_{0}} ∇ 〈 {G}^{Φ} , {∇}^{′} \cdot J 〉 + 〈 {\overline{G}}^{EM} , M 〉 , \qquad ( 126 )$$
and the magnetic field being expressed as
$$H = - j ω {ε}_{0} 〈 {\overline{K}}^{F} , M 〉 + \frac{1}{j ω {μ}_{0}} ∇ 〈 {G}^{Ψ} , {∇}^{′} \cdot M 〉 + 〈 {\overline{G}}^{HJ} , J 〉 , \qquad ( 127 )$$
where the dyadic K̅^{A} has components
$${\overline{K}}^{A} = [ \begin{matrix}{K}_{xx}^{A} & 0 & {K}_{xz}^{A} \\ 0 & {K}_{yy}^{A} & {K}_{yz}^{A} \\ {K}_{zx}^{A} & {K}_{zy}^{A} & {K}_{zz}^{4}\end{matrix} ] , \qquad ( 128 )$$
and its spectral domain components are defined by equivalent transmission line Green's functions (TLGFs) Vᵢ^{p},Vᵥ^{p},Iᵢ^{p}, and Iᵥ^{p}, where for the transverse magnetic (TM) polarization p=e and for the transverse electric (TE) polarization p=h, as
$${\tilde{K}}_{xx}^{A} = {\tilde{K}}_{yy}^{A} = \frac{1}{j ω {μ}_{0}} {V}_{i}^{h} , \qquad ( 129 )$$
$${\tilde{K}}_{xz}^{A} = \frac{{μ}_{t}^{′} {k}_{x}}{{jk}_{ρ}^{2}} ( {V}_{v}^{h} - {V}_{v}^{e} ) , \qquad ( 130 )$$
$${\tilde{K}}_{yz}^{A} = \frac{{μ}_{t}^{′} {k}_{y}}{{jk}_{ρ}^{2}} ( {V}_{v}^{h} - {V}_{v}^{e} ) , \qquad ( 131 )$$
$${\tilde{K}}_{zz}^{A} = \frac{1}{j ω {ε}_{0}} [ ( \frac{{μ}_{t}}{{ε}_{z}^{′}} + \frac{{ν}^{e} {μ}_{t}^{′}}{{ε}_{t}^{′}} - \frac{{μ}_{t}^{′} {k}_{t}^{2}}{{ε}_{t} {k}_{ρ}^{2}} ) {I}_{v}^{e} + \frac{{k}_{0}^{2} {μ}_{t} {μ}_{t}^{′}}{{k}_{ρ}^{2}} {I}_{v}^{h} ] , \qquad ( 132 )$$
$${\tilde{G}}^{Φ} = \frac{j ω {ε}_{0}}{{k}_{ρ}^{2}} ( {V}_{i}^{e} - {V}_{i}^{h} ) , \qquad ( 133 )$$
and the spatial domain K̅^{A} and G^{Φ} are obtained by performing inverse Fourier transform of (129) to (133), in which, kₜ²=k₀²μₜεₜ, k₀²=ω²μ₀ε₀, the relative permittivity dyadic ε̅=Īₜεₜ+\hat{z}\hat{z}ε_{z}, relative permeability dyadic μ̅=Īₜμₜ+\hat{z}\hat{z}μ_{z}, and electric and magnetic anisotropy ratio v^{e}=εₜ/ε_{z} and v^{h}=μₜ/μ_{z}, where the subscripts t and z mean the parameter in the transverse plane and z direction, respectively, and ε′ and μ′ represent physical quantities associated with the layer containing the source elevation z′; and
(ii) evaluating mixed potential Green's functions K̅^{A} and G^{Φ} using the Spectral Differential Equation Approximation Method (SDEAM) to solve for the electric field according to (126), while mixed potential Green's functions K̅^{F} and G^{Ψ} in mixed representation of H (127) is related to TLGFs according to (129) to (132) and replacement of symbols A→F, Φ→Ψ, ε→μ, μ→ε, V→I, I→V, v→i, i→v, e→h, h→e and also can be solved by SDEAM.

2. The method according to claim 1 wherein the use of SDEAM further includes:
(i) expressing the mixed potential Green's functions in terms of TLGFs defined as one dimensional (1D) boundary value problems (BVPs) where each BVP consists of an differential equation (DE), boundary conditions (BCs) at layer interfaces and BCs at top and bottom boundaries;
(ii) casting a 1D BVP numerically into a system of linear algebraic equations (SLAE) in the form of
(A^{X}+k_{ρ}²B^{X})X=b (134)
where A^{X} and B^{X} are known invertible matrices, X is the vector holding some unknown TLGF coefficients at discretisation nodes, b is a known vector of excitation;
(iii) performing matrix decomposition E^{X}D^{X}(E^{X})⁻¹=(B^{X})⁻¹A^{X} where D^{X} is a diagonal matrix;
(iv) representing the solution to the SLAE in a pole-residue form.
X=E^{X}(D^{X}+k_{ρ}²I)⁻¹T^{X}b (135)
where T^{X}=(B^{X}E^{X})⁻¹;
(v) analytically evaluating pertinent inverse Fourier transform integrals with the integrands involving X defined in the pole-residue form.

3. The method outlined in claim 2 for use in either a 2.5D or fully 3D electromagnetic analysis, in which Kₓₓ^{A} and G^{Φ} mixed potential Green's function components are necessary, the method further comprising: defining the 1D BVPs for TLGF's voltages Vᵢ^{h} and Vᵢ^{e}, in which the differential equation of Vᵢ^{h} is defined as
$$\frac{{d}^{2} {V}_{i}^{h}}{{dz}^{2}} + ( {k}_{t}^{2} - {ν}^{h} {k}_{ρ}^{2} ) {V}_{i}^{h} = - j ω {μ}_{0} {μ}_{t} δ ( z - {z}^{′} ) , \qquad ( 136 )$$
and the boundary conditions at layer interfaces are defined as
$${{{{{V}_{i}^{h} \vert}_{{z}_{int}^{-}} = {V}_{i}^{h} \vert}_{{z}_{int}^{+}} , ( \frac{1}{{μ}_{t}} \frac{{dV}_{i}^{h}}{dz} ) \vert}_{{z}_{int}^{-}} = ( \frac{1}{{μ}_{t}} \frac{{dV}_{i}^{h}}{dz} ) \vert}_{{z}_{int}^{+}} , \qquad ( 137 )$$
and if the medium is fully shielded, defining the boundary conditions at top and bottom perfect electric conductor (PEC) ground plates as
$${{{V}_{i}^{h} \vert}_{{z}_{g}^{b}} = 0 , {V}_{i}^{h} \vert}_{{z}_{g}^{t}} = 0 , \qquad ( 138 )$$
if the medium is partially open on top, defining the boundary conditions at bottom PEC ground plate and top truncation boundary as
$${{{{V}_{i}^{h} \vert}_{{z}_{g}^{b}} = 0 , \frac{{dV}_{i}^{h}}{dz} \vert}_{{z}^{t}} + j \sqrt{{k}_{0}^{2} - {k}_{ρ}^{2}} {V}_{i}^{h} \vert}_{{z}^{t}} = 0 , \qquad ( 139 )$$
if the medium is partially open on bottom, defining the boundary conditions at bottom truncation boundary and top PEC ground plate as
$$\frac{{dV}_{i}^{h}}{dz} {\vert}_{{z}^{b}} - j \sqrt{{k}_{0}^{2} - {k}_{ρ}^{2}} {V}_{i}^{h} {\vert}_{{z}^{b}} = 0 , {V}_{i}^{h} {\vert}_{{z}_{g}^{t}} = 0 , \qquad ( 140 )$$
if the medium is fully open, defining the boundary conditions at top and bottom truncation boundaries as
$$\frac{{dV}_{i}^{h}}{dz} {\vert}_{{z}^{b}} - j \sqrt{{k}_{0}^{2} - {k}_{ρ}^{2}} {V}_{i}^{h} {\vert}_{{z}^{b}} = 0 , \frac{{dV}_{i}^{h}}{dz} {\vert}_{{z}^{t}} + j \sqrt{{k}_{0}^{2} - {k}_{ρ}^{2}} {V}_{i}^{h} {\vert}_{{z}^{t}} = 0 , \qquad ( 141 )$$
and the BVP of Vᵢ^{e} consisting of the differential equation defined as
$$\frac{{d}^{2} {V}_{i}^{e}}{{dz}^{2}} + ( {k}_{t}^{2} - {v}^{e} {k}_{ρ}^{2} ) {V}_{i}^{e} = - j \frac{{k}_{t}^{2} - {k}_{ρ}^{2}}{{ωε}_{0} {ε}_{t}} δ ( z - {z}^{′} ) , \qquad ( 142 )$$
boundary conditions at layer interfaces defined as
$${V}_{i}^{e} {\vert}_{{z}_{int}^{-}} = {V}_{i}^{e} {\vert}_{{z}_{int}^{+}} , ( \frac{{ωε}_{0} {ε}_{t}}{{k}_{t}^{2} - {k}_{ρ}^{2}} \frac{{dV}_{i}^{e}}{dz} ) {\vert}_{{z}_{int}^{-}} = ( \frac{{ωε}_{0} {ε}_{t}}{{k}_{t}^{2} - {k}_{ρ}^{2}} \frac{{dV}_{i}^{e}}{dz} ) {\vert}_{{z}_{int}^{+}} , \qquad ( 143 )$$
and if the medium is fully shielded, defining the boundary conditions at top and bottom PEC ground plates as
$${V}_{i}^{e} {\vert}_{{z}_{g}^{b}} = 0 , {V}_{i}^{e} {\vert}_{{z}_{g}^{t}} = 0 , \qquad ( 144 )$$
if the medium is partially open on top, defining the boundary conditions at bottom PEC plate and top truncation boundary as
$${V}_{i}^{e} {\vert}_{{z}_{g}^{b}} = 0 , \frac{{dV}_{i}^{e}}{dz} {\vert}_{{z}^{t}} + j \sqrt{{k}_{0}^{2} - {k}_{ρ}^{2}} {V}_{i}^{e} {\vert}_{{z}^{t}} = 0 , \qquad ( 145 )$$
if the medium is partially open on bottom, defining the boundary conditions at bottom truncation boundary and top PEC plate as
$$\frac{{dV}_{i}^{e}}{dz} {\vert}_{{z}^{b}} - j \sqrt{{k}_{0}^{2} - {k}_{ρ}^{2}} {V}_{i}^{e} {\vert}_{{z}^{b}} = 0 , {V}_{i}^{e} {\vert}_{{z}_{g}^{t}} = 0 , \qquad ( 146 )$$
if the medium is fully open, defining the boundary conditions at top and bottom truncation boundaries as
$$\frac{{dV}_{i}^{e}}{dz} {\vert}_{{z}^{b}} - j \sqrt{{k}_{0}^{2} - {k}_{ρ}^{2}} {V}_{i}^{e} {\vert}_{{z}^{b}} = 0 , \\ \frac{{dV}_{i}^{e}}{dz} {\vert}_{{z}^{t}} + j \sqrt{{k}_{0}^{2} - {k}_{ρ}^{2}} {V}_{i}^{e} {\vert}_{{z}^{t}} = 0 , \qquad ( 147 )$$
with expressing the elevation of an dielectric layer interface of the layered medium as zᵢₙₜ, the elevations of the bottom and top PEC ground plates as z_{g}^{b} and z_{g}^{t} respectively, the elevations of the bottom and top truncation boundaries as z^{b} and z^{t} respectively.

4. The method of claim 3 further comprising: transforming the BVP of Vᵢ^{e} to such DE
$$\frac{{d}^{2} {\hat{V}}_{i}^{e}}{{dz}^{2}} + ( {k}_{t}^{2} - {v}^{e} {k}_{ρ}^{2} ) {\hat{V}}_{i}^{e} = - j δ ( z - {z}^{′} ) , \qquad ( 148 )$$
boundary conditions at layer interfaces
$$( \frac{{k}_{t}^{2} - {v}^{e} {k}_{ρ}^{2}}{{ωε}_{0} {ε}_{t}} {\hat{V}}_{i}^{e} ) {\vert}_{{z}_{int}^{-}} = ( \frac{{k}_{t}^{2} - {v}^{e} {k}_{ρ}^{2}}{{ωε}_{0} {ε}_{t}} {\hat{V}}_{i}^{e} ) {\vert}_{{z}_{int}^{+}} , \\ ( \frac{d {\hat{V}}_{i}^{e}}{dz} ) {\vert}_{{z}_{int}^{-}} = ( \frac{d {\hat{V}}_{i}^{e}}{dz} ) {\vert}_{{z}_{int}^{+}} , \qquad ( 149 )$$
and if the medium is fully shielded, defining the boundary conditions at top and bottom PEC ground plates as
$${\hat{V}}_{i}^{e} {\vert}_{{z}_{g}^{b}} = 0 , {\hat{V}}_{i}^{e} {\vert}_{{z}_{g}^{t}} = 0 , \qquad ( 150 )$$
if the medium is partially open on top, defining the boundary conditions at bottom PEC plate and top truncation boundary as
$${\hat{V}}_{i}^{e} {\vert}_{{z}_{g}^{b}} = 0 , \frac{d {\hat{V}}_{i}^{e}}{dz} {\vert}_{{z}^{t}} + j \sqrt{{k}_{0}^{2} - {k}_{ρ}^{2}} {\hat{V}}_{i}^{e} {\vert}_{{z}^{t}} = 0 , \qquad ( 151 )$$
if the medium is partially open on bottom, defining the boundary conditions at bottom truncation boundary and top PEC plate as
$$\frac{d {\hat{V}}_{i}^{e}}{dz} {\vert}_{{z}^{b}} - j \sqrt{{k}_{0}^{2} - {k}_{ρ}^{2}} {\hat{V}}_{i}^{e} {\vert}_{{z}^{b}} = 0 , {\hat{V}}_{i}^{e} {\vert}_{{z}_{g}^{t}} = 0 , \qquad ( 152 )$$
if the medium is fully open, defining the boundary conditions at top and bottom truncation boundaries as
$$\frac{d {\hat{V}}_{i}^{e}}{dz} {\vert}_{{z}^{b}} - j \sqrt{{k}_{0}^{2} - {k}_{ρ}^{2}} {\hat{V}}_{i}^{e} {\vert}_{{z}^{b}} = 0 , \\ \frac{d {\hat{V}}_{i}^{e}}{dz} {\vert}_{{z}^{t}} + j \sqrt{{k}_{0}^{2} - {k}_{ρ}^{2}} {\hat{V}}_{i}^{e} {\vert}_{{z}^{t}} = 0 , \qquad ( 153 )$$
with the transform defined as
$${\hat{V}}_{i}^{e} = \frac{{ωε}_{0} {ε}_{t}}{{k}_{t}^{2} - {v}^{e} {k}_{ρ}^{2}} {V}_{i}^{e} \qquad ( 154 )$$
to benefit subsequent pole residue representation of Vᵢ^{e}.

5. The method according to claim 4, wherein the medium is not fully shielded such that the medium is partially open on bottom, partially open on top, or fully open, the method further comprising: representing the square root in a radiation boundary condition (RBC) as
$$\frac{1}{\sqrt{{k}_{0}^{2} - {k}_{ρ}^{2}}} ≅ {\sum }_{p = 1}^{P - 1} \frac{{C}_{p}}{{k}_{ρ}^{2} - {α}_{p}} + {C}_{0} \qquad ( 155 )$$
where Cₚ are known coefficients, αₚ are known poles generated by the VECTFIT algorithm, introducing auxiliary variables
$${E}_{p} = \frac{{C}_{p}}{{k}_{ρ}^{2} - {α}_{p}} \frac{dV}{dz} {\vert}_{{z}_{N}} , p = 1 , 2 , ⋯ , P \qquad ( 156 )$$
to the corresponding SLAE where V can be Vᵢ^{h} or \tilde{V}ᵢ^{e} order to combine the ODE and RBC at the open medium boundary truncation while still enabling pole residue representations of Vᵢ^{h} and Vᵢ^{e}.

6. The method of claim 5 further comprising: representing the pole residue expressions of Vᵢ^{h} and Vᵢ^{e} at the nth discretization node as
$${V}_{i , n}^{h} = {\sum }_{s ∈ S} {b}_{s}^{{V}_{i}^{h}} {\sum }_{m = 1}^{{N}_{c}} \frac{{E}_{nm}^{{V}_{i}^{h}} {T}_{ms}^{{V}_{i}^{h}}}{{D}_{mm}^{{V}_{i}^{h}} + {k}_{ρ}^{2}} , \qquad ( 157 )$$
$${V}_{i , n}^{e} = \frac{{k}_{t , n}^{2}}{{ωε}_{0} {ε}_{t , n}} {\sum }_{s ∈ S} {b}_{s}^{{\hat{V}}_{i}^{e}} {\sum }_{m = 1}^{{N}_{d}} \frac{{E}_{nm}^{{\hat{V}}_{i}^{e}} {T}_{ms}^{{\hat{V}}_{i}^{e}}}{{D}_{mm}^{{\hat{V}}_{i}^{e}} + {k}_{ρ}^{2}} - \frac{{v}_{n}^{e}}{{ωε}_{0} {ε}_{t , n}} {\sum }_{s ∈ S} {b}_{s}^{{\hat{V}}_{i}^{e}} {\sum }_{m = 1}^{{N}_{d}} \frac{{E}_{nm}^{{\hat{V}}_{i}^{e}} {T}_{ms}^{{\hat{V}}_{i}^{e}} {k}_{ρ}^{2}}{{D}_{mm}^{{\hat{V}}_{i}^{e}} + {k}_{ρ}^{2}} , \qquad ( 158 )$$
with the set S containing the non-zero entries of the RHS vector b, N_{c} and N_{d} being the size of the SLAE of Vᵢ^{h} and \hat{V}ᵢ^{e} respectively.

7. The method in claim 6 further comprising: performing the analytical inverse Fourier transform on \tilde{K}ₓₓ^{A} and \tilde{G}^{Φ}, which leads to spatial domain closed form summation
$${K}_{xx , n}^{A} = \frac{1}{2 π j {ωμ}_{0}} {\sum }_{s ∈ S} {b}_{s}^{{V}_{i}^{h}} {\sum }_{m = 1}^{{N}_{c}} {E}_{nm}^{{V}_{i}^{h}} {T}_{ms}^{{V}_{i}^{h}} {η}_{1} ( {D}_{mm}^{{V}_{i}^{h}} , ρ ) \qquad ( 159 )$$
$${G}_{n}^{Φ} = \frac{j}{2 π} [ ( \frac{{k}_{t , n}^{2}}{{ε}_{t , n}} ) {\sum }_{s ∈ S} {b}_{s}^{{\hat{V}}_{i}^{e}} {\sum }_{m = 1}^{{N}_{c}} {E}_{nm}^{{\hat{V}}_{i}^{e}} {T}_{ms}^{{\hat{V}}_{i}^{e}} {η}_{3} ( {D}_{mm}^{{\hat{V}}_{i}^{e}} , ρ ) - \frac{{v}_{e , n}}{{ε}_{t , n}} \text{} {\sum }_{s ∈ S} {b}_{s}^{{\hat{V}}_{i}^{e}} {\sum }_{m = 1}^{{N}_{c}} {E}_{nm}^{{\hat{V}}_{i}^{e}} {T}_{ms}^{{\hat{V}}_{i}^{e}} {η}_{1} ( {D}_{mm}^{{\hat{V}}_{i}^{e}} , ρ ) - {ωε}_{0} {\sum }_{s ∈ S} {b}_{s}^{{V}_{i}^{h}} {\sum }_{m = 1}^{{N}_{d}} {E}_{nm}^{{V}_{i}^{h}} {T}_{ms}^{{V}_{i}^{h}} {η}_{3} ( {D}_{mm}^{{V}_{i}^{h}} , ρ ) ] \qquad ( 160 )$$
wherein the function η₁, and η₃ are
$${η}_{1} ( {D}_{mm} , ρ ) = - \frac{π j}{2} {H}_{0}^{( 2 )} ( - j \sqrt{{D}_{mm}} ρ ) \qquad ( 161 )$$
$${η}_{3} ( {D}_{mm} , ρ ) = - \frac{π j}{2 {D}_{mm}} {H}_{0}^{( 2 )} ( - j \sqrt{{D}_{mm}} ρ ) . \qquad ( 162 )$$

8. The method outlined in claim 3 for use in a shielded full 3D electromagnetic analysis problem, in which all components of mixed potential Green's functions K̅^{A} and G^{Φ} are needed, the method further comprising: defining 1D BVPs for currents Iᵥ^{e} and Iᵥ^{h}, in which the BVP of Iᵥ^{e} contains the DE
$$\frac{{d}^{2} {I}_{v}^{e}}{{dz}^{2}} + ( {k}_{t}^{2} - {v}^{e} {k}_{ρ}^{2} ) {I}_{v}^{e} = - j {ωε}_{0} {ε}_{t} δ ( z - {z}^{′} ) , \qquad ( 163 )$$
boundary conditions at layer interfaces
$$( \frac{1}{{ε}_{t}} \frac{{dI}_{v}^{e}}{dz} ) {\vert}_{{z}_{int}^{-}} = ( \frac{1}{{ε}_{t}} \frac{{dI}_{v}^{e}}{dz} ) {\vert}_{{z}_{int}^{+}} , {I}_{v}^{e} {\vert}_{{z}_{int}^{-}} = {I}_{v}^{e} {\vert}_{{z}_{int}^{+}} , \qquad ( 164 )$$
and if the medium is fully shielded, defining the boundary conditions at top and bottom PEC ground plates as
$$\frac{{dI}_{v}^{e}}{dz} {\vert}_{{z}_{g}^{b}} = 0 , \frac{{dI}_{v}^{e}}{dz} {\vert}_{{z}_{g}^{t}} = 0 , \qquad ( 165 )$$
if the medium is partially open on top, defining the boundary conditions at bottom PEC plate and top truncation boundary as
$$\frac{{dI}_{v}^{e}}{dz} {\vert}_{{z}_{g}^{b}} = 0 , \frac{{dI}_{v}^{e}}{dz} {\vert}_{{z}^{t}} + j \sqrt{{k}_{0}^{2} - {k}_{ρ}^{2}} {I}_{v}^{e} {\vert}_{{z}^{t}} = 0 , \qquad ( 166 )$$
if the medium is partially open on bottom, defining the boundary conditions at bottom truncation boundary and top PEC plate as
$$\frac{{dI}_{v}^{e}}{dz} {\vert}_{{z}^{b}} - j \sqrt{{k}_{0}^{2} - {k}_{ρ}^{2}} {I}_{v}^{e} {\vert}_{{z}^{b}} = 0 , \frac{{dI}_{v}^{e}}{dz} {\vert}_{{z}_{g}^{t}} = 0 , \qquad ( 167 )$$
if the medium is fully open, defining the boundary conditions at top and bottom truncation boundaries as
$$\frac{{dI}_{v}^{e}}{dz} {\vert}_{{z}^{b}} - j \sqrt{{k}_{0}^{2} - {k}_{ρ}^{2}} {I}_{v}^{e} {\vert}_{{z}^{b}} = 0 , \frac{{dI}_{v}^{e}}{dz} {\vert}_{{z}^{t}} + j \sqrt{{k}_{0}^{2} - {k}_{ρ}^{2}} {I}_{v}^{e} {\vert}_{{z}^{t}} = 0 , \qquad ( 168 )$$
and defining the BVP of Iᵥ^{h} containing DE
$$\frac{{d}^{2} {I}_{v}^{h}}{{dz}^{2}} + ( {k}_{t}^{2} - {v}^{h} {k}_{ρ}^{2} ) {I}_{v}^{h} = - j \frac{{k}_{t}^{2} - {k}_{ρ}^{2}}{{ωε}_{0} {ε}_{t}} δ ( z - {z}^{′} ) , \qquad ( 169 )$$
boundary conditions at layer interfaces
$${I}_{v}^{h} {\vert}_{{z}_{int}^{-}} = {I}_{v}^{h} {\vert}_{{z}_{int}^{+}} , ( \frac{{ωμ}_{0} {μ}_{t}}{{k}_{t}^{2} - {k}_{ρ}^{2}} \frac{{dI}_{v}^{h}}{dz} ) {\vert}_{{z}_{int}^{-}} = ( \frac{{ωμ}_{0} {μ}_{t}}{{k}_{t}^{2} - {k}_{ρ}^{2}} \frac{{dI}_{v}^{h}}{dz} ) {\vert}_{{z}_{int}^{+}} , \qquad ( 170 )$$
and if the medium is fully shielded, definimg the boundary conditions at top and bottom PEC ground plates as
$$\frac{{dI}_{v}^{h}}{dz} {\vert}_{{z}_{g}^{b}} = 0 , \frac{{dI}_{v}^{h}}{dz} {\vert}_{{z}_{g}^{t}} = 0 , \qquad ( 171 )$$
if the medium is partially open on top, defining the boundary conditions at bottom PEC plate and top truncation boundary as
$$\frac{{dI}_{v}^{h}}{dz} {\vert}_{{z}_{g}^{b}} = 0 , \frac{{dI}_{v}^{h}}{dz} {\vert}_{{z}^{t}} + j \sqrt{{k}_{0}^{2} - {k}_{ρ}^{2}} {I}_{v}^{h} {\vert}_{{z}^{t}} = 0 , \qquad ( 172 )$$
if the medium is partially open on bottom, defining the boundary conditions at bottom truncation boundary and top PEC plate as
$$\frac{{dI}_{v}^{h}}{dz} {\vert}_{{z}^{b}} - j \sqrt{{k}_{0}^{2} - {k}_{ρ}^{2}} {I}_{v}^{h} {\vert}_{{z}^{b}} = 0 , \frac{{dI}_{v}^{h}}{dz} {\vert}_{{z}_{g}^{t}} = 0 , \qquad ( 173 )$$
if the medium is fully open, defining the boundary conditions at top and bottom truncation boundaries as
$$\frac{{dI}_{v}^{h}}{dz} {\vert}_{{z}^{b}} - j \sqrt{{k}_{0}^{2} - {k}_{ρ}^{2}} {I}_{v}^{h} {\vert}_{{z}^{b}} = 0 , \frac{{dI}_{v}^{h}}{dz} {\vert}_{{z}^{t}} + j \sqrt{{k}_{0}^{2} - {k}_{ρ}^{2}} {I}_{v}^{h} {\vert}_{{z}^{t}} = 0. \qquad ( 174 )$$

9. The method according to claim 8 further comprising: transforming the BVP of Iᵥ^{h} to such DE
$$\frac{{d}^{2} {\hat{I}}_{v}^{h}}{{dz}^{2}} + ( {k}_{t}^{2} - {v}^{h} {k}_{ρ}^{2} ) {\hat{I}}_{v}^{h} = - j δ ( z - {z}^{′} ) , \qquad ( 175 )$$
boundary conditions at layer interfaces
$$( \frac{{k}_{t}^{2} - {v}^{h} {k}_{ρ}^{2}}{{ωμ}_{0} {μ}_{t}} {\hat{I}}_{v}^{h} ) {\vert}_{{z}_{int}^{-}} = ( \frac{{k}_{t}^{2} - {v}^{h} {k}_{ρ}^{2}}{{ωμ}_{0} {μ}_{t}} {\hat{I}}_{v}^{h} ) {\vert}_{{z}_{int}^{+}} , \\ ( \frac{d {\hat{I}}_{v}^{h}}{dz} ) {\vert}_{{z}_{int}^{-}} = ( \frac{d {\hat{I}}_{v}^{h}}{dz} ) {\vert}_{{z}_{int}^{+}} , \qquad ( 176 )$$
and if the medium is fully shielded, defining the boundary conditions at top and bottom PEC ground plates as
$$\frac{d {\hat{I}}_{v}^{h}}{dz} {\vert}_{{z}_{g}^{b}} = 0 , \frac{d {\hat{I}}_{v}^{h}}{dz} {\vert}_{{z}_{g}^{t}} = 0 , \qquad ( 177 )$$
if the medium is partially open on top, defining the boundary conditions at bottom PEC plate and top truncation boundary as
$$\frac{d {\hat{I}}_{v}^{h}}{dz} {\vert}_{{z}_{g}^{b}} = 0 , \frac{d {\hat{I}}_{v}^{h}}{dz} {\vert}_{{z}^{t}} + j \sqrt{{k}_{0}^{2} - {k}_{ρ}^{2}} {\hat{I}}_{v}^{h} {\vert}_{{z}^{t}} = 0 , \qquad ( 178 )$$
if the medium is partially open on bottom, defining the boundary conditions at bottom truncation boundary and top PEC plate as
$$\frac{d {\hat{I}}_{v}^{h}}{dz} {\vert}_{{z}^{b}} - j \sqrt{{k}_{0}^{2} - {k}_{ρ}^{2}} {\hat{I}}_{v}^{h} {\vert}_{{z}^{b}} = 0 , \frac{d {\hat{I}}_{v}^{h}}{dz} {\vert}_{{z}_{g}^{t}} = 0 , \qquad ( 179 )$$
if the medium is fully open, defining the boundary conditions at top and bottom truncation boundaries as
$$\frac{d {\hat{I}}_{v}^{h}}{dz} {\vert}_{{z}^{b}} - j \sqrt{{k}_{0}^{2} - {k}_{ρ}^{2}} {\hat{I}}_{v}^{h} {\vert}_{{z}^{b}} = 0 , \\ \frac{d {\hat{I}}_{v}^{h}}{dz} {\vert}_{{z}^{t}} + j \sqrt{{k}_{0}^{2} - {k}_{ρ}^{2}} {\hat{I}}_{v}^{h} {\vert}_{{z}^{t}} = 0. \qquad ( 180 )$$
with the transform defined as
$${\hat{I}}_{v}^{h} = \frac{{ωμ}_{0} {μ}_{t}}{{k}_{t}^{2} - {v}^{h} {k}_{ρ}^{2}} {I}_{v}^{h} , \qquad ( 181 )$$
to benefit the pole residue representation of Iᵥ^{h}.

10. The method according to claim 9, wherein the medium is not fully shielded such that the medium is partially open on bottom, partially open on top, or fully open, the method further comprising: representing the square root in a radiation boundary condition (RBC) as
$$\frac{1}{\sqrt{{k}_{0}^{2} - {k}_{ρ}^{2}}} ≅ {\sum }_{p = 1}^{P - 1} \frac{{C}_{p}}{{k}_{ρ}^{2} - {α}_{p}} + {C}_{0} \qquad ( 182 )$$
where Cₚ are known coefficients, αₚ are known poles generated by the VECTFIT algorithm, introducing auxiliary variables
$${E}_{p} = \frac{{C}_{p}}{{k}_{ρ}^{2} - {α}_{p}} \frac{dI}{dz} {\vert}_{{z}_{N}} , p = 1 , 2 , ⋯ , P \qquad ( 183 )$$
to the corresponding SLAE where I can be Iᵥ^{e} or Îᵥ^{h} in order to combine the ODE and RBC at the open medium boundary truncation while still enabling pole residue representations of Iᵥ^{e} and Iᵥ^{h}.

11. The method according to claim 10 further comprising: formulating pole-residue expressions of TLGFs Iᵥ^{h} and Iᵥ^{e} as
$${I}_{v , n}^{h} = \frac{{k}_{t , n}^{2}}{{ωμ}_{0} {μ}_{t , n}} {\sum }_{s ∈ S} {b}_{s}^{{\hat{I}}_{v}^{h}} {\sum }_{m = 1}^{{N}_{d}} \frac{{E}_{nm}^{{\hat{I}}_{v}^{h}} {T}_{ms}^{{\hat{I}}_{v}^{h}}}{{D}_{mm}^{{\hat{I}}_{v}^{h}} + {k}_{ρ}^{2}} - \frac{{v}_{n}^{h}}{{ωμ}_{0} {μ}_{t , n}} {\sum }_{s ∈ S} {b}_{s}^{{\hat{I}}_{v}^{h}} {\sum }_{m = 1}^{{N}_{d}} \frac{{E}_{nm}^{{\hat{I}}_{v}^{h}} {T}_{ms}^{{\hat{I}}_{v}^{h}} {k}_{ρ}^{2}}{{D}_{mm}^{{\hat{I}}_{v}^{h}} + {k}_{ρ}^{2}} , \qquad ( 184 )$$
$${I}_{v , n}^{e} = {\sum }_{s ∈ S} {b}_{s}^{{I}_{v}^{e}} {\sum }_{m = 1}^{{N}_{c}} \frac{{E}_{nm}^{{I}_{v}^{e}} {T}_{ms}^{{I}_{v}^{e}}}{{D}_{mm}^{{I}_{v}^{e}} + {k}_{ρ}^{2}} . \qquad ( 185 )$$

12. The method according to claim 11 further comprising: subsequent to obtaining the pole-residue representations of Vᵢ^{h}, Vᵢ^{e}, Iᵥ^{e}, and Iᵥ^{h}, taking each of their derivatives to obtain the pole-residue forms of TLGFs Iᵢ^{h}, Iᵢ^{e}, Vᵥ^{e}, and Vᵥ^{h}.

13. The method according to claim 12 further comprising: using high-order numerical methods for solving the TLGFs of Vᵢ^{h}, Vᵢ^{e}, Iᵥ^{e}, and Iᵥ^{h} taking the derivatives of the results, which leads to pole-residue forrns of Iᵢ^{h}, Iᵢ^{e}, Vᵥ^{e}, and Vᵥ^{h} as
$${I}_{i , n}^{h} = \frac{j}{{ωμ}_{0} {μ}_{t}^{{k}_{n}}} {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{V}_{i}^{h}} {\sum }_{m = 1}^{{N}_{c}} \frac{{E}_{{n}_{q}^{{k}_{n}} m}^{{V}_{i}^{h}} {T}_{ms}^{{V}_{i}^{h}}}{{D}_{mm}^{{V}_{i}^{h}} + {k}_{ρ}^{2}} \qquad ( 186 )$$
$${I}_{i , n}^{e} = j {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{\hat{V}}_{i}^{e}} {\sum }_{m = 1}^{{N}_{d}} \frac{{E}_{{n}_{q}^{{k}_{n}} m}^{{\hat{V}}_{i}^{e}} {T}_{ms}^{{\hat{V}}_{i}^{e}}}{{D}_{mm}^{{\hat{V}}_{i}^{e}} + {k}_{ρ}^{2}} \qquad ( 187 )$$
$${V}_{v , n}^{e} = \frac{j}{{ωε}_{0} {ε}_{t}^{{k}_{n}}} {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{I}_{v}^{e}} {\sum }_{m = 1}^{{N}_{c}} \frac{{E}_{{n}_{q}^{{k}_{n}} m}^{{I}_{v}^{e}} {T}_{ms}^{{I}_{v}^{e}}}{{D}_{mm}^{{I}_{v}^{e}} + {k}_{ρ}^{2}} \qquad ( 188 )$$
$${V}_{v , n}^{h} = j {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{\hat{I}}_{v}^{h}} {\sum }_{m = 1}^{{N}_{d}} \frac{{E}_{{n}_{q}^{{k}_{n}} m}^{{\hat{I}}_{v}^{h}} {T}_{ms}^{{\hat{I}}_{v}^{h}}}{{D}_{mm}^{{\hat{I}}_{v}^{h}} + {k}_{ρ}^{2}} \qquad ( 189 )$$
where kₙ being the index of the element that contains the nth discretization node, and l_{q} being the basis function.

14. The method according to claim 13 further comprising: formulating components K_{xz}^{A}, K_{yz}^{A}, and K_{zz}^{A} the dyadic Green's function K̅^{A} in the spatial domain through the evaluation of the inverse Fourier transform as
$$\{ \begin{matrix}{K}_{xz , n}^{A} \\ {K}_{yz , n}^{A}\end{matrix} \} = \{ \begin{matrix}cos α \\ sin α\end{matrix} \} ( \frac{j {μ}_{t}^{′}}{2 {πωε}_{0} {ε}_{t}^{{k}_{n}}} {\sum }_{q = 1}^{{N}_{p}^{{k}_{n}}} {( {l}_{q}^{{k}_{n}} )}^{′} {\vert}_{{z}_{n}} {\sum }_{s ∈ S} {b}_{s}^{{I}_{v}^{e}} {\sum }_{m = 1}^{{N}_{c}} {E}_{{n}_{q}^{{k}_{n}} m}^{{I}_{v}^{e}} {T}_{ms}^{{I}_{v}^{e}} {η}_{2} ( {D}_{mm}^{{I}_{v}^{e}} , ρ ) - \frac{j {μ}_{t}^{′}}{2 π} {\sum }_{q = 1}^{{N}^{{k}_{n}}} {( {l}_{q}^{{k}_{n}} )}^{′} {\vert}_{{z}_{n}} {\sum }_{s ∈ S} {b}_{s}^{{\hat{I}}_{v}^{h}} {\sum }_{m = 1}^{{N}_{d}} {E}_{{n}_{q}^{{k}_{n}} m}^{{\hat{I}}_{v}^{h}} {T}_{ms}^{{\hat{I}}_{v}^{h}} {η}_{2} ( {D}_{mm}^{{\hat{I}}_{v}^{h}} , ρ ) ) \qquad ( 190 )$$
$${K}_{zz , n}^{A} = \frac{1}{2 π j {ωμ}_{0}} [ ( \frac{{μ}_{t}^{{k}_{n}}}{{ε}_{z}^{′}} + {v}_{e}^{{k}_{n}} \frac{{μ}_{t}^{′}}{{ε}_{t}^{{k}_{n}}} ) {\sum }_{s ∈ S} {b}_{s}^{{I}_{v}^{e}} {\sum }_{m = 1}^{{N}_{c}} {E}_{nm}^{{I}_{v}^{e}} {T}_{ms}^{{I}_{v}^{e}} {η}_{1} ( {D}_{mm}^{{I}_{v}^{e}} , ρ ) - \frac{{( {k}_{t}^{2} )}^{{k}_{n}} {μ}_{t}^{′}}{{ε}_{t}^{{k}_{n}}} {\sum }_{s ∈ S} {b}_{s}^{{I}_{v}^{e}} {\sum }_{m = 1}^{{N}_{c}} {E}_{nm}^{{I}_{v}^{e}} {T}_{ms}^{{I}_{v}^{e}} {η}_{3} ( {D}_{mm}^{{I}_{v}^{e}} , ρ ) + {ωε}_{0} {{μ}_{t}^{′} ( {k}_{t}^{2} )}^{{k}_{n}} {\sum }_{s ∈ S} {b}_{s}^{{\hat{I}}_{v}^{h}} {\sum }_{m = 1}^{{N}_{d}} {E}_{nm}^{{\hat{I}}_{v}^{h}} {T}_{ms}^{{\hat{I}}_{v}^{h}} {η}_{3} ( {D}_{mm}^{{\hat{I}}_{v}^{h}} , ρ ) - {ωε}_{0} {{μ}_{t}^{′} ( {v}^{h} )}^{{k}_{n}} {\sum }_{s ∈ S} {b}_{s}^{{\hat{I}}_{v}^{h}} {\sum }_{m = 1}^{{N}_{d}} {E}_{nm}^{{\hat{I}}_{v}^{h}} {T}_{ms}^{{\hat{I}}_{v}^{h}} {η}_{1} ( {D}_{mm}^{{\hat{I}}_{v}^{h}} , ρ ) ] \qquad ( 191 )$$
$$where$$
$${η}_{2} ( {D}_{mm} , ρ ) = \frac{π}{2 \sqrt{{D}_{mm}}} {H}_{1}^{( 2 )} ( - j \sqrt{{D}_{mm}} ρ ) . \qquad ( 192 )$$

15. The method according to claim 14 further comprising: obtaining components K_{zx}^{A} and K_{zy}^{A} from reciprocity relationships
$${K}_{zx}^{A} ( ρ , {z}^{′} \vert z ) = - \frac{{μ}_{t}}{{μ}_{t}^{′}} {K}_{xz}^{A} ( p , z \vert {z}^{′} ) , \qquad ( 193 )$$
$${K}_{zy}^{A} ( ρ , {z}^{′} \vert z ) = - \frac{{μ}_{t}}{{μ}_{t}^{′}} {K}_{yz}^{A} ( p , z \vert {z}^{′} ) . \qquad ( 194 )$$

16. The method according to any one of claims 1 through 15 wherein conductive elements comprise interconnects within a circuit assembly and the multilayered medium comprises stratified layers of the circuit assembly, the method including solving for electric current in the circuit assembly.

17. The method according to any one of claims 1 through 15 wherein the conductive grounding element comprises a structural metal frame embedded within a concrete foundation structure and the multilayered medium comprises layers of earth soil, the method including solving for electric current in both the conductive grounding elements and the concrete foundation structure.

18. The method according to any one of claims 1 through 15 wherein dielectric elements comprise optical interconnects within an integrated photonics assembly the multilayered medium comprises stratified layers of the photonics assembly, the method including solving for electric and magnetic currents in the photonics assembly.

19. The method according to any one of claims 1 through 15 wherein dielectric elements comprise underground natural resource formations within the layers of soil and the multilayered medium comprises layers of Earth strata, the method including solving for electric and magnetic currents in the natural resource formations.

20. The method according to any one of claims 1 through 15 wherein dielectric elements comprise sea ice formations within the ocean ice sheets and the multilayered medium comprises layers of sea ice, water, and snow, the method including solving for electric and magnetic currents in the natural and man-made irregularities present in the layers.
